(19) United States
(12) Patent Application Publication
(10) Pub. No.: US 2024/0422991 A1
(43) Pub. Date: Dec. 19, 2024

(54) VERTICAL MEMORY DEVICE INCLUDING SELECTOR WITH VARIABLE RESISTIVE MATERIAL

(71) Applicant: SAMSUNG ELECTRONICS CO., LTD., Suwon-si (KR)

(72) Inventors: Youngsun Song, Suwon-si (KR); Seulji Song, Suwon-si (KR)

(21) Appl. No.: 18/402,552

(22) Filed: Jan. 2, 2024

(30) Foreign Application Priority Data
Jun. 19, 2023 (KR) 10-2023-0078356

(51) Int. Cl. H10B 63/00; G11C 13/00; H10N 70/00

(52) U.S. Cl. CPC H10B 63/24; G11C 13/0026; G11C 13/0028; G11C 13/0038; H10B 63/84; H10N 70/066; H10N 70/826

(57) ABSTRACT

A vertical memory device includes a memory cell structure extending primarily in a vertical direction. A resistive layer is electrically connected to a first end of the memory cell structure. A selector is electrically connected to a second end of the memory cell structure and includes a variable resistive material of which an electrical resistive value is reversibly changed in response to an electrical signal. A first bit line is located apart from the memory cell structure in the vertical direction with the resistive layer disposed therebetween and is connected to the resistive layer. A second bit line is located apart from the memory cell structure in the vertical direction with the selector disposed therebetween and is connected to the selector. A plurality of word line plates are spaced apart from each other in the vertical direction and overlapping each other in the vertical direction. Each word line plate at least partially surrounds a portion of a sidewall of the memory cell structure.

### CROSS-REFERENCE TO RELATED APPLICATION

This application is based on and claims priority under 35 U.S.C. § 119 to Korean Patent Application No. 10-2023-0078356, filed on Jun. 19, 2023, in the Korean Intellectual Property Office, the disclosure of which is incorporated by reference herein in its entirety.

### TECHNICAL FIELD

The inventive concept relates to a memory device, and more particularly, to a vertical memory device including a selector having a variable resistive material.

### SUMMARY

A vertical memory device includes a memory cell structure extending primarily in a vertical direction. A resistive layer is electrically connected to a first end of the memory cell structure. A selector is electrically connected to a second end of the memory cell structure. The selector includes a variable resistive material of which an electrical resistive value is reversibly changed in response to an electrical signal. A first bit line is spaced apart from the memory cell structure in the vertical direction with the resistive layer disposed therebetween. The first bit line is electrically connected to the resistive layer. A second bit line is spaced apart from the memory cell structure in the vertical direction with the selector disposed therebetween. The second bit line is electrically connected to the selector. A plurality of word line plates are spaced apart from each other in the vertical direction and overlap each other in the vertical direction. Each of the plurality of word line plates at least partially surrounds a portion of a sidewall of the memory cell structure.

A vertical memory device includes a plurality of memory cell structures repeatedly arranged in a first lateral direction and a second lateral direction that intersect with each other. Each of the plurality of memory cell structures extends primarily in a vertical direction. Each of a plurality of resistive layers is electrically connected to a first end of a corresponding one of the plurality of memory cell structures in the vertical direction. Each of a plurality of selectors is electrically connected to another one of a corresponding one of the plurality of memory cell structures in the vertical direction and including a variable resistive material of which an electrical resistive value is reversibly changed in response to an electrical signal. A plurality of first bit lines are spaced apart from the plurality of memory cell structures in the vertical direction with the plurality of resistive layers disposed therebetween. Each of the plurality of first bit lines is electrically connected to a series of resistive layers arranged in a line in the first lateral direction, from among the plurality of resistive layers. A plurality of second bit lines are spaced apart from the plurality of memory cell structures in the vertical direction with the plurality of selectors disposed therebetween. Each second bit line is electrically connected to a series of selectors arranged in a line in the second lateral direction, from among the plurality of selectors. A plurality of word line plates are spaced apart from each other in the vertical direction and overlap each other in the vertical direction. Each of the plurality of word line plates at least partially surrounds a portion of a sidewall of each of the plurality of memory cell structures.

A vertical memory device includes a plurality of memory cell structures repeatedly arranged in a first lateral direction and a second lateral direction that intersect with each other. Each of the plurality of memory cell structures extends primarily in a vertical direction and includes a conductive pillar and at least one cell variable resistive layer at least partially surrounding the conductive pillar. The at least one cell variable resistive layer includes a first ovonic threshold switching (OTS) material layer. Each of a plurality of resistive layers is electrically connected to a first end of a corresponding one of the plurality of memory cell structures. Each of a plurality of selectors is electrically connected to a second end of a corresponding one of the plurality of memory cell structures and includes a second OTS material layer. Each of a plurality of first bit lines is electrically connected to a series of resistive layers arranged in a line in the first lateral direction, from among the plurality of resistive layers. Each of a plurality of second bit lines is electrically connected to a series of selectors arranged in a line in the second lateral direction, from among the plurality of selectors. A plurality of word line plates are spaced apart from each other in the vertical direction and overlap each other in the vertical direction. Each of the plurality of word line plates at least partially surround a portion of a sidewall of each of the plurality of memory cell structures.

### BRIEF DESCRIPTION OF THE DRAWINGS

Embodiments of the inventive concept will be more clearly understood from the following detailed description taken in conjunction with the accompanying drawings in which:

FIG. 1 is a perspective view of a vertical memory device according to embodiments of the present disclosure;

FIG. 2A is a cross-sectional view of the vertical memory device taken along line X1-X1′ of FIG. 1;

FIG. 2B is a cross-sectional view of the vertical memory device taken along line Y1-Y1′ of FIG. 1;

FIG. 2C is a plan view of components of the vertical memory device of FIG. 1;

FIG. 3 is a perspective view of a vertical memory device according to embodiments of the present disclosure;

FIGS. 4A and 4B are cross-sectional views of a vertical memory device according to embodiments of the present disclosure;

FIGS. 5A and 5B are cross-sectional views of a vertical memory device according to embodiments of the present disclosure;

FIGS. 6A and 6B are cross-sectional views of a vertical memory device according to embodiments of the present disclosure;

FIGS. 7A and 7B are cross-sectional views of a vertical memory device according to embodiments of the present disclosure;

FIGS. 8A and 8B are cross-sectional views of a vertical memory device according to embodiments of the present disclosure;

FIGS. 9A and 9B are cross-sectional views of a vertical memory device according to embodiments of the present disclosure;

FIG. 10 is a cross-sectional view of a vertical memory device according to embodiments of the present disclosure;

FIG. 11 is a plan view of components of a vertical memory device according to embodiments of the present disclosure;

FIG. 12 is a diagram illustrating a voltage change in each of a turn-off section and a turn-on section of a selector including an ovonic threshold switching (OTS) material in a vertical memory device according to embodiments of the present disclosure;

FIG. 13 is a circuit diagram illustrating a turn-off state in a vertical memory device according to embodiments of the present disclosure;

FIG. 14 is a circuit diagram illustrating a turn-on state in a vertical memory device according to embodiments of the present disclosure;

FIGS. 15A, 15B, and 15C are circuit diagrams illustrating voltage behavior of an unselected conductive pillar in a vertical memory device according to embodiments of the present disclosure;

FIGS. 16A to 26B are cross-sectional views illustrating a method of manufacturing a vertical memory device, according to embodiments of the present disclosure;

FIGS. 16A, 17A, 18A, 19A, 20A, 21A, 22A, 23A, 24A, 25A, and 26A are cross-sectional views of a portion corresponding to a cross-section taken along line X1-X1′ of FIG. 1, according to a process sequence;

FIGS. 16B, 17B, 18B, 19B, 20B, 21B, 22B, 23B, 24B, 25B, and 26B are cross-sectional views of a portion corresponding to a cross-section taken along line Y1-Y1′ of FIG. 1, according to a process sequence;

FIGS. 27A to 29B are cross-sectional views illustrating a method of manufacturing a vertical memory device, according to embodiments of the present disclosure;

FIGS. 27A, 28A, and 29A are cross-sectional views of a portion corresponding to a cross-section taken along line X1-X1′ of FIG. 1, according to a process sequence;

FIGS. 27B, 28B, and 29B are cross-sectional views of a portion corresponding to a cross-section taken along line Y1-Y1′ of FIG. 1;

FIGS. 30A to 34B are cross-sectional views illustrating a method of manufacturing a vertical memory device, according to embodiments of the present disclosure;

FIGS. 30A, 31A, 32A, 33A, and 34A are cross-sectional views of a portion corresponding to a cross-section taken along line X1-X1′ of FIG. 1, according to a process sequence; and

FIGS. 30B, 31B, 32B, 33B, and 34B are cross-sectional views of a portion corresponding to a cross-section taken along line Y1-Y1′ of FIG. 1.

### DETAILED DESCRIPTION OF THE EMBODIMENTS

Hereinafter, embodiments of the present disclosure will be described in detail with reference to the accompanying drawings. The same reference numerals may be used to denote the same elements in the drawings, and to the extent that an element has not been described herein, it may be assumed that the element is at least similar to a corresponding element that has been described elsewhere within the present disclosure.

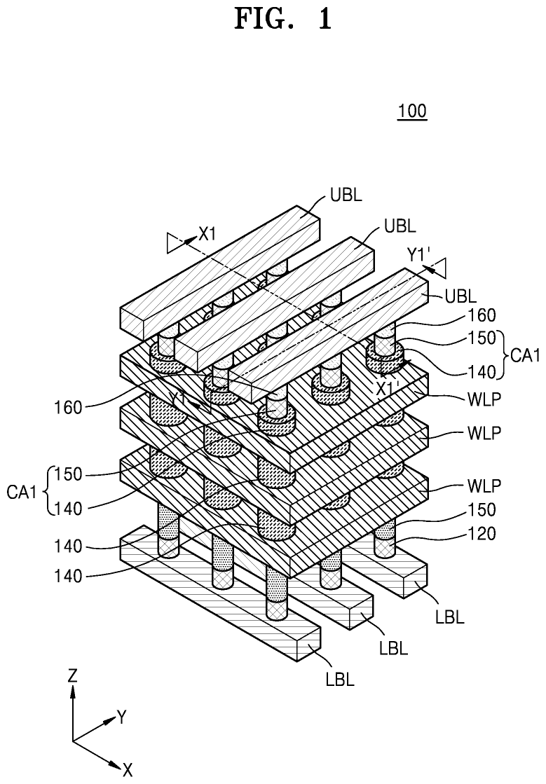

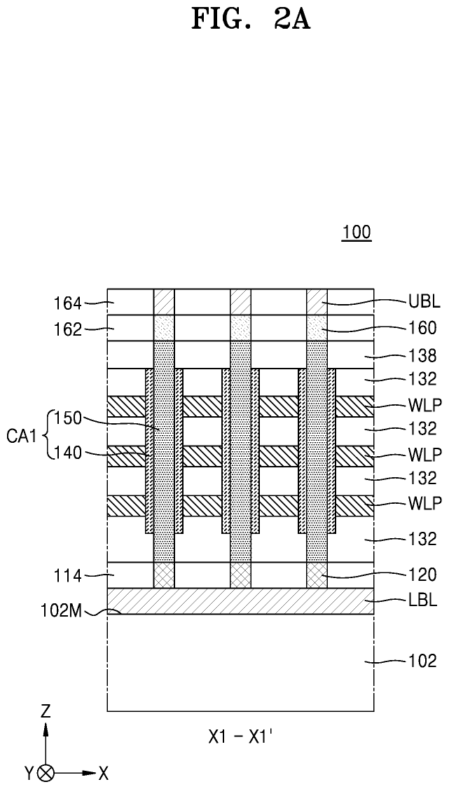

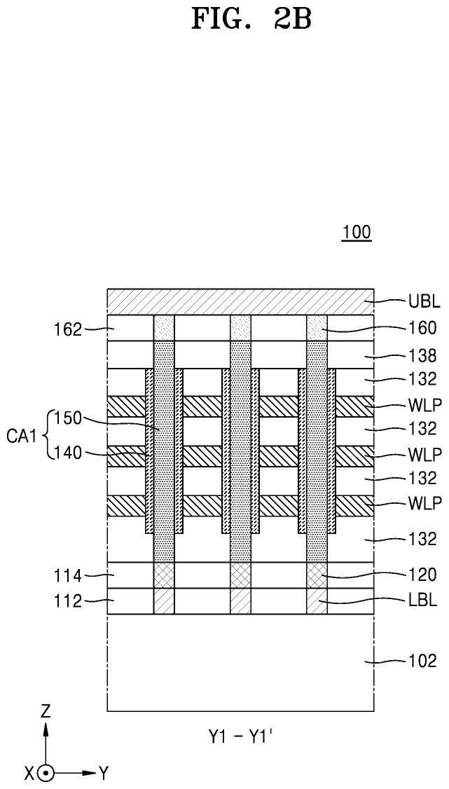

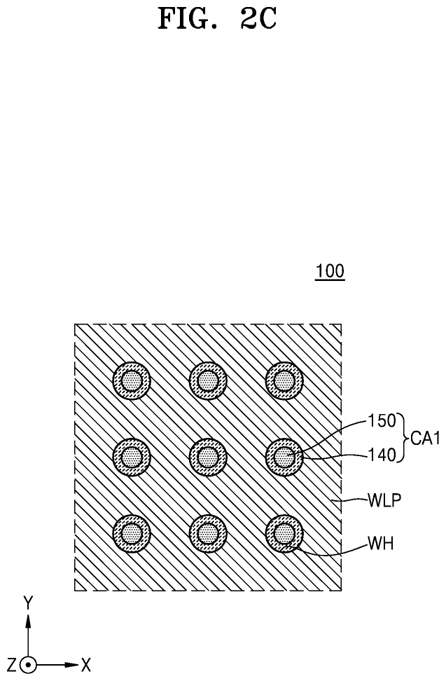

FIG. 1 is a perspective view of a vertical memory device 100 according to embodiments of the present disclosure. FIG. 2A is a cross-sectional view of the vertical memory device 100 taken along line X1-X1′ of FIG. 1. FIG. 2B is a cross-sectional view of the vertical memory device 100 taken along line Y1-Y1′ of FIG. 1. FIG. 2C is a plan view of components of the vertical memory device 100.

Referring to FIGS. 1 and 2A to 2C, the vertical memory device 100 may include a plurality of memory cell structures CA1, which are repeatedly arranged in a first lateral direction (e.g., X direction) and a second lateral direction (e.g., Y direction), which intersect with each other on a substrate 102. The substrate 102 may support the plurality of memory cell structures CA1. The substrate 102 may include a silicon substrate or an insulating substrate. In embodiments of the present disclosure, the substrate 102 may include a silicon substrate and an insulating film covering the silicon substrate. Each of the plurality of memory cell structures CA1 may extend primarily in a vertical direction (e.g., Z direction) on the substrate 102.

Each of the plurality of memory cell structures CA1 may include a conductive pillar 150 and a cell variable resistive layer 140. The conductive pillar 150 may extend primarily in the vertical direction (e.g., Z direction). The cell variable resistive layer 140 may at least partially surround the conductive pillar 150 and extend primarily in the vertical direction (e.g., Z direction). The conductive pillar 150 may include a doped polysilicon film, a metal film, or a combination thereof. The metal film may include tungsten (W), without necessarily being limited thereto. In embodiments of the present disclosure, the cell variable resistive layer 140 may include a variable resistive material of which an electrical resistive value is reversibly changed in response to an electrical signal.

A plurality of resistive layers 120 may be disposed between the substrate 102 and the plurality of memory cell structures CA1. Each of the plurality of resistive layers 120 may be connected to a first end of a selected one of the conductive pillars 150 included in the plurality of memory cell structures CA1 in the vertical direction (e.g., Z direction). The conductive pillar 150 and the resistive layer 120 may be in contact with each other. From among end portions of each of the plurality of conductive pillars 150 in the vertical direction (e.g., Z direction), an end portion in contact with the resistive layer 120 may be referred to as a first end portion.

At a vertical level at which the plurality of resistive layers 120 are located, a space between two adjacent ones of the plurality of resistive layers 120 may be filled by a first insulating plate 114. As used herein, the term “vertical level” refers to a distance from a main surface 102M of the substrate 102 in the vertical direction (e.g., Z direction). The first insulating plate 114 may include a plurality of holes through which the plurality of resistive layers 120 pass. In embodiments, each of the plurality of resistive layers 120 may include a silicon oxide film, and the first insulating plate 114 may include a silicon nitride film, without necessarily being limited thereto.

A plurality of selectors 160 may be disposed on the plurality of memory cell structures CA1. The plurality of selectors 160 may be spaced apart from the substrate 102 in the vertical direction (e.g., Z direction) with the plurality of memory cell structures CA1 disposed therebetween. Each of the plurality of selectors 160 may be connected to a second end of the selected one of the conductive pillars 150 included in the plurality of memory cell structures CA1 in the vertical direction (e.g., Z direction). The conductive pillar 150 and the selector 160 may be in contact with each other. From among the end portions of each of the plurality of conductive pillars 150) in the vertical direction (e.g., Z direction), an end portion in contact with the selector 160 may be referred to as a second end portion. In embodiments, each of the plurality of selectors 160 may include a variable resistive material of which an electrical resistive value is reversibly changed in response to an electrical signal.

At a vertical level at which the plurality of selectors 160 are located, a space between two adjacent ones of the plurality of selectors 160 may be filled by a second insulating plate 162. The second insulating plate 162 may include a plurality of holes through which the plurality of selectors 160 pass. In embodiments, the second insulating plate 162 may include a silicon oxide film, a silicon nitride film, or a combination thereof, without necessarily being limited thereto.

In embodiments, in the plurality of memory cell structures CA1, each of a plurality of cell variable resistive layers 140 and the plurality of selectors 160 may include an ovonic threshold switching (OTS) material layer. The OTS material may include a chalcogenide switching material.

In embodiments, each of the plurality of cell variable resistive layers 140 and the plurality of selectors 160 may include a single layer or a multilayered film, which includes at least one material selected from binary materials (e.g., GeSe, GeS, AsSe, AsTe, AsS, SiTe, SiSe, SiS, GeAs, SiAs, SnSe, and SnTe), ternary materials (e.g., GeAsTe, GeAsSe, AlAsTe, AlAsSe, SiAsSe, SiAsTe, GeSeTe, GeSeSb, GaAsSe, GaAsTe, InAsSe, InAsTe, SnAsSe, and SnAsTe), quaternary materials (e.g., GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeIn, GeAsSeGa, GeAsSeAl, GeAsSeTl, GeAsSeSn, GeAsSeZn, GeAsTeIn, GeAsTeGa, GeAsTeAl, GeAsTeTl, GeAsTeSn, and GeAsTeZn), quinary materials (e.g., GeSiAsSeTe, GeAsSeTeS, GeSiAsSeS, GeSiAsTeS, GeSiSeTeS, GeSiAsSeP, GeSiAsTeP, GeAsSeTeP, GeSiAsSeIn, GeSiAsSeGa, GeSiAsSeAl, GeSiAsSeTl, GeSiAsSeZn, GeSiAsSeSn, GeSiAsTeIn, GeSiAsTeGa, GeSiAsTeAl, GeSiAsTeTl, GeSiAsTeZn, GeSiAsTeSn, GeAsSeTeIn, GeAsSeTeGa, GeAsSeTeAl, GeAsSeTeTl, GeAsSeTeZn, GeAsSeTeSn, GeAsSeSIn, GeAsSeSGa, GeAsSeSAl, GeAsSeSTl, GeAsSeSZn, GeAsSeSSn, GeAsTeSIn, GeAsTeSGa, GeAsTeSAl, GeAsTeSTl, GeAsTeSZn, GeAsTeSSn, GeAsSeInGa, GeAsSeInAl, GeAsSeInTl, GeAsSeInZn, GeAsSeInSn, GeAsSeGaAl, GeAsSeGaTl, GeAsSeGaZn, GeAsSeGaSn, GeAsSeAlTl, GeAsSeAlZn, GeAsSEAlSn, GeAsSeTlZn, GeAsSeTlSn, and GeAsSeZnSn), and senary materials (e.g., GeSiAsSeTeS, GeSiAsSeTeIn, GeSiAsSeTeGa, GeSiAsSeTeAl, GeSiAsSeTeTl, GeSiAsSeTeZn, GeSiAsSeTeSn, GeSiAsSeTeP, GeSiAsSeSIn, GeSiAsSeSGa, GeSiAsSeSAl, GeSiAsSeSTl, GeSiAsSeSZn, GeSiAsSeSSn, GeAsSeTeSIn, GeAsSeTeSGa, GeAsSeTeSAl, GeAsSeTeSTl, GeAsSeTeSZn, GeAsSeTeSSn, GeAsSeTePIn, GeAsSeTePGa, GeAsSeTePAl, GeAsSeTePTl, GeAsSeTePZn, GeAsSeTePSn, GeSiAsSeInGa, GeSiAsSeInAl, GeSiAsSeInTl, GeSiAsSeInZn, GeSiAsSeInSn, GeSiAsSeGaAl, GeSiAsSeGaTl, GeSiAsSeGaZn, GeSiAsSeGaSn, GeSiAsSeAlSn, GeAsSeTeInGa, GeAsSeTeInAl, GeAsSe TeInTl, GeAsSeTeInZn, GeAsSeTeInSn, GeAsSeTeGaAl, GeAsSe TeGaTl, GeAsSeTeGaZn, GeAsSeTeGaSn, GeAsSeTeAlSn, GeAsSeSInGa, GeAsSeSInAl, GeAsSeSInTl, GeAsSeSInZn, GeAsSeSInSn, GeAsSeSGaAl, GeAsSeSGaTl, GeAsSeSGaZn, GeAsSeSGaSn, and GeAsSeSAlSn). In other embodiments, each of the plurality of cell variable resistive layers 140 and the plurality of selectors 160 may include at least one material selected from the binary to senary materials described above and at least one additional element selected from boron (B), carbon (C), nitrogen (N), and oxygen (O).

In embodiments, in the plurality of memory cell structures CA1, the plurality of cell variable resistive layers 140 and the plurality of selectors 160 may include the same material selected from the OTS materials described above. In embodiments, in the plurality of memory cell structures CA1, the plurality of cell variable resistive layers 140 and the plurality of selectors 160 may include different materials selected from the OTS materials described above.

On the substrate 102, a plurality of word line plates WLP may be at a vertical level between a vertical level at which the plurality of cell variable resistive layers 140 are located and a vertical level at which the plurality of selectors 160 are located. The plurality of word line plates WLP may overlap each other and be spaced apart from each other in the vertical direction (e.g., Z direction). Each of the plurality of word line plates WLP may at least partially surround a portion of a sidewall of each of the plurality of memory cell structures CA1.

At the same vertical level as a selected one of the plurality of word line plates WLP, a planar structure of the word line plate WLP, a plurality of conductive pillars 150, and the plurality of cell variable resistive layers 140 is illustrated in FIG. 2C. As shown in FIG. 2C, each of the plurality of word line plates WLP may include a flat plate having a plurality of through holes WH through which the plurality of memory cell structures CA1 pass in the vertical direction (e.g., Z direction). In a view from above (on an X-Y plane), each of the plurality of cell variable resistive layers 140 may have a ring shape at least partially surrounding the conductive pillar 150.

In the plurality of memory cell structures CA1, each of the plurality of cell variable resistive layers 140 may be in contact with the plurality of word line plates WLP, and each of the plurality of conductive pillars 150 may be spaced apart from the plurality of word line plates WLP in a lateral direction (e.g., X direction and/or Y direction) with the cell variable resistive layer 140 disposed therebetween. The plurality of cell variable resistive layers 140 may be respectively disposed between the conductive pillar 150 and the plurality of word line plates WLP and be in contact with the conductive pillar 150 and the plurality of word line plates WLP, respectively.

As shown in FIGS. 1, 2A, and 2B, the plurality of cell variable resistive layers 140 and the plurality of selectors 160 may be spaced apart from each other in the vertical direction (e.g., Z direction). For example, a vertical level at which the plurality of selectors 160 are located may be higher than a vertical level at which the plurality of cell variable resistive layers 140 are located.

A plurality of first bit lines LBL may be connected to the plurality of resistive layers 120. Each of the plurality of resistive layers 120 may be in contact with a selected one of the plurality of first bit lines LBL. The plurality of first bit lines LBL may be disposed between the substrate 102 and the plurality of resistive layers 120. The plurality of first bit lines LBL may be spaced apart from the plurality of memory cell structures CA1 in the vertical direction (e.g., Z direction) with the plurality of resistive layers 120 disposed therebetween. Each of the plurality of first bit lines LBL may be connected to a series of resistive layers 120 arranged in a line in the first lateral direction (e.g., X direction), from among the plurality of resistive layer 120. For example, from among the plurality of resistive layers 120, a series of resistive layers 120 arranged in a line in the first lateral direction (e.g., X direction) may be connected to one first bit line LBL. A space between two adjacent ones of the plurality of first bit lines LBL may be filled by the first insulating pattern 112. The first insulating pattern 112 may include a silicon oxide film, without necessarily being limited thereto.

A plurality of second bit lines UBL may be connected to the plurality of selectors 160. Each of the plurality of selectors 160 may be in contact with a selected one of the plurality of second bit lines UBL. The plurality of second bit lines UBL may be spaced apart from the plurality of memory cell structures CA1 in the vertical direction (e.g., Z direction) with the plurality of selectors 160 disposed therebetween. Each of the plurality of second bit lines UBL may be connected to a series of selectors 160 arranged in a line in the second lateral direction (e.g., Y direction), from among the plurality of selectors 160. For example, from among the plurality of selectors 160, a series of selectors 160 arranged in a line in the second lateral direction (e.g., Y direction) may be connected to one second bit line UBL. A space between two adjacent ones of the plurality of second bit lines UBL may be filled by a second insulating pattern 164. The second insulating pattern 164 may include a silicon oxide film, without necessarily being limited thereto.

In embodiments, each of the plurality of first bit lines LBL, the plurality of second bit lines UBL, and the plurality of word line plates WLP may include a doped polysilicon film, a metal film, or a combination thereof. For example, each of the plurality of first bit lines LBL, the plurality of second bit lines UBL, and the plurality of word line plates WLP may include tungsten (W), without necessarily being limited thereto.

In the vertical direction (e.g., Z direction), the plurality of first bit lines LBL and the plurality of resistive layers 120 may be disposed between the substrate 102 and the plurality of memory cell structures CA1. The plurality of second bit lines UBL and the plurality of selectors 160 may be spaced apart from the substrate 102 in the vertical direction (e.g., Z direction) with the plurality of memory cell structures CA1 disposed therebetween.

As shown in FIGS. 2A and 2B, a bottom surface and a top surface of each of the plurality of word line plates WLP may be covered by an isolation insulating film 132. As used herein, the bottom surface of each of the plurality of word line plates WLP may refer to a surface facing the substrate 102, and a top surface of each of the plurality of word line plates WLP may refer to a surface opposite to the bottom surface of each of the plurality of word line plates WLP. The plurality of memory cell structures CA1 may include portions at least partially surrounded by a plurality of isolation insulating films 132. A top surface of each of the plurality of cell variable resistive layers 140 and a top surface of an uppermost one of the plurality of isolation insulating films 132 may be covered by an upper insulating film 138. Each of the plurality of conductive pillars 150 may include a portion at least partially surrounded by the upper insulating film 138. Each of the plurality of isolation insulating films 132 and the upper insulating film 138 may include a silicon oxide film, without necessarily being limited thereto.

FIGS. 1 and 2A to 2C illustrate an example in which the plurality of memory cell structures CA1 are arranged in a matrix form in the first lateral direction (e.g., X direction) and the second lateral direction (e.g., Y direction) in a view from above (on an X-Y plane), but the inventive concept is not necessarily limited thereto. For example, in a view from above (in an X-Y plane), the plurality of memory cell structures CA1 may be arranged in a hexagonal array.

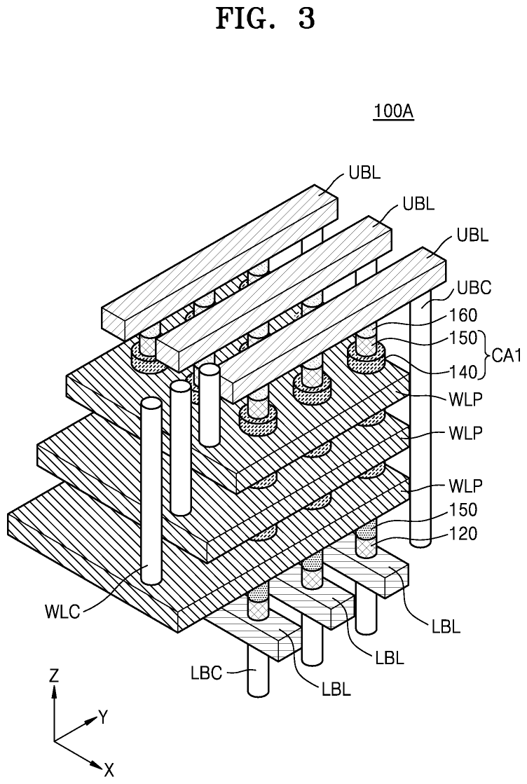

FIG. 3 is a perspective view of a vertical memory device 100A according to embodiments of the present disclosure. In FIG. 3, the same reference numerals may be used to denote the same elements as in FIGS. 1 and 2A to 2C, and to the extent that an element has not been described herein, it may be assumed that the element is at least similar to a corresponding element that has been described elsewhere within the present disclosure.

Referring to FIG. 3, the vertical memory device 100A may substantially have the same configuration as the vertical memory device 100 described with reference to FIGS. 1 and 2A to 2C. However, the vertical memory device 100A may include a plurality of first contact structures LBC, a plurality of second contact structures UBC, and a plurality of third contact structures WLC. The plurality of first contact structures LBC may be connected to a plurality of first bit lines LBL to apply an operating voltage to the plurality of first bit lines LBL. The plurality of second contact structures UBC may be connected to a plurality of second bit lines UBL to apply an operating voltage to the plurality of second bit lines UBL. The plurality of third contact structures WLC may be connected to a plurality of word line plates WLP to apply an operating voltage to the plurality of word line plates WLP.

Respective positions and shapes of the plurality of first contact structures LBC, the plurality of second contact structures UBC, and the plurality of third contact structures WLC are not necessarily limited to the examples shown in FIG. 3 and may be variously modified within the scope of the inventive concept.

The vertical memory devices 100 and 100A described with reference to FIGS. 1 to 3 may have a structure in which a resistive layer 120 and a selector 160, which are respectively connected to a lower portion and an upper portion of a conductive pillar 150 of one memory cell structure CA1, are connected in series with the conductive pillar 150 disposed therebetween. Accordingly, a structure in which the selector 160, the conductive pillar 150, and the resistive layer 120 are connected in series may constitute one unit vertical electrode. A lower portion of the one unit vertical electrode may be connected to the first bit line LBL, and an upper portion of the one unit vertical electrode may be connected to the second bit line UBL to form a cross-point structure.

When the selector 160 includes an OTS material and a voltage of a threshold voltage Vth or higher is applied to both ends of the selector 160, a resistance of the selector 160 may be rapidly reduced due to a threshold switching phenomenon, thereby causing a turn-on state in which current flows. When current of a specific threshold value Ihold or less flows through the selector 160 in the turn-on state, the resistance of the selector 160 may rapidly increase again, thereby causing a turn-off state in which current hardly flows through the selector 160.

In embodiments, in, components, sizes, and thicknesses of the vertical memory devices 100 and 100A may be adjusted to satisfy a condition where a resistance of the resistive layer 120 is lower than a resistance of the selector 160 in a turn-off state of one unit vertical electrode and higher than a resistance of the selector 160 in a turn-on state of the one unit vertical electrode.

The vertical memory devices 100 and 100A described with reference to FIGS. 1 to 3 may include a selector 160 of a pillar type, which has a simplified structure that may be manufactured using a simplified process, and the selector 160 may include an OTS material. In the vertical memory devices 100 and 100A, by selecting two bit lines (i.e., one first bit line LBL and one second bit line UBL) extending in directions crossing each other at a lower side and an upper side of the memory cell structure CA1 to be selected, the selector 160 connected to the memory cell structure CA1 to be selected may be activated, and thus, the memory cell structure CA1 to be selected may be selected. In the vertical memory devices 100 and 100A according to the inventive concept, because a sufficient current may be supplied to the selector 160, the selector 160 connected between the first bit line LBL and the second bit line UBL that extend in directions intersecting with each other may be activated, and thus, a desired voltage may be applied to the memory cell structure CA1 to be selected. Accordingly, the selector 160 having a simplified structure connected to the memory cell structure CA1 to be selected may be activated without employing a transistor having a relatively complicated structure (e.g., a vertical channel structure) as a selector as in a typical structure, thereby enabling random access to a desired memory cell. Therefore, according to the inventive concept, the vertical memory devices 100 and 100A having increased integration density and reliability may be provided.

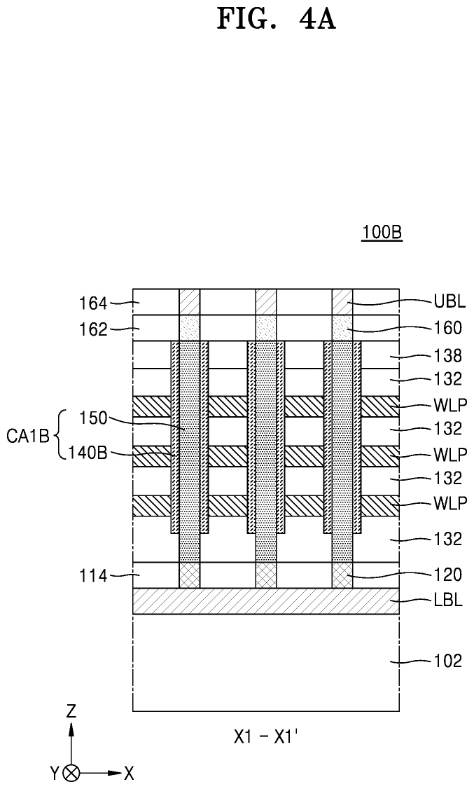

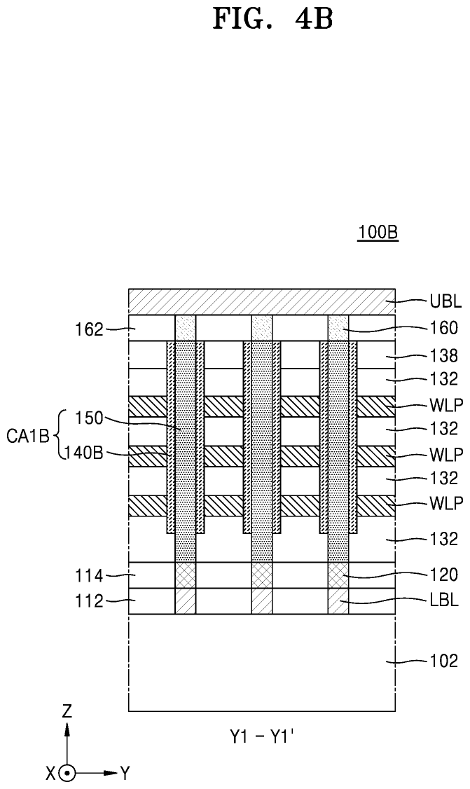

FIGS. 4A and 4B are cross-sectional views of a vertical memory device 100B according to embodiments of the present disclosure. FIG. 4A illustrates a cross-sectional configuration of a portion of the vertical memory device 100B, which corresponds to a cross-section taken along line X1-X1′ of FIG. 1. FIG. 4B illustrates a cross-sectional configuration of a portion of the vertical memory device 100B, which corresponds to a cross-section taken along line Y1-Y1′ of FIG. 1. In FIGS. 4A and 4B, the same reference numerals may be used to denote the same elements as in FIGS. 1 and 2A to 2C, and to the extent that an element has not been described herein, it may be assumed that the element is at least similar to a corresponding element that has been described elsewhere within the present disclosure.

Referring to FIGS. 4A and 4B, the vertical memory device 100B may substantially have the same configuration as the vertical memory device 100 described with reference to FIGS. 1 and 2A to 2C. However, the vertical memory device 100B may include a plurality of memory cell structures CA1B, each of which includes a conductive pillar 150 and a cell variable resistive layer 140B.

A plurality of cell variable resistive layers 140B may substantially have the same configuration as the plurality of cell variable resistive layers 140 described with reference to FIGS. 1 and 2A to 2C. However, the plurality of cell variable resistive layers 140B may pass through an upper insulating film 138 in a vertical direction (e.g., Z direction). A top surface of each of the plurality of cell variable resistive layers 140B may substantially be at the same vertical level as a bottom surface of each of a plurality of selectors 160. The vertical memory device 100B may substantially provide the same effects as those of the vertical memory device 100 and 100A described with reference to FIGS. 1 to 3.

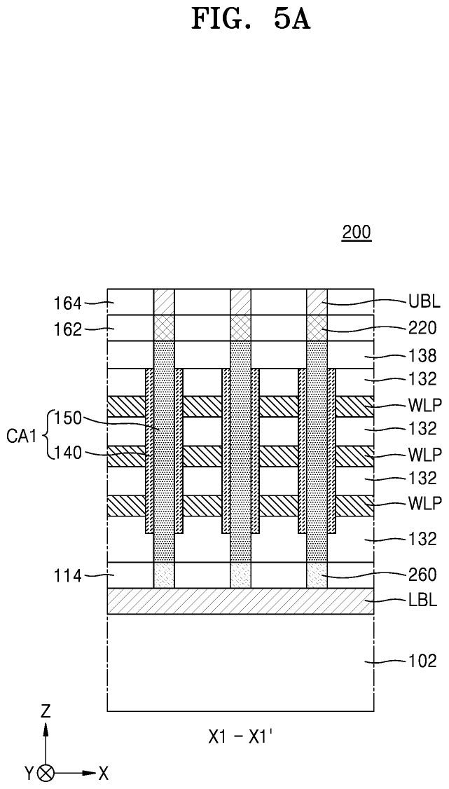

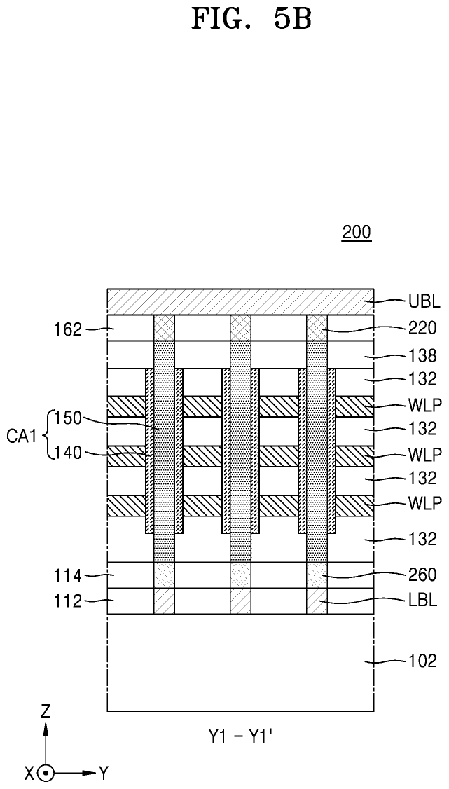

FIGS. 5A and 5B are cross-sectional views of a vertical memory device 200 according to embodiments of the present disclosure. FIG. 5A illustrates a cross-sectional configuration of a portion of the vertical memory device 200, which corresponds to a cross-section taken along line X1-X1′ of FIG. 1. FIG. 5B illustrates a cross-sectional configuration of a portion of the vertical memory device 200, which corresponds to a cross-section taken along line Y1-Y1′ of FIG. 1. In FIGS. 5A and 5B, the same reference numerals may be used to denote the same elements as in FIGS. 1 and 2A to 2C, and to the extent that an element has not been described herein, it may be assumed that the element is at least similar to a corresponding element that has been described elsewhere within the present disclosure.

Referring to FIGS. 5A and 5B, the vertical memory device 200 may substantially have the same configuration as the vertical memory device 100 described with reference to FIGS. 1 and 2A to 2C. However, the vertical memory device 200 may include a plurality of selectors 260 disposed between the plurality of first bit lines LBL and the plurality of memory cell structures CA1 and a plurality of resistive layers 220 disposed between the plurality of memory cell structures CA1 and a plurality of second bit lines UBL.

The plurality of resistive layers 220 may be spaced apart from a substrate 102 in a vertical direction (e.g., Z direction) with the plurality of memory cell structures CA1 disposed therebetween. The plurality of selectors 260 may be disposed between the substrate 102 and the plurality of memory cell structures CA1. Each of the plurality of resistive layers 220 may be connected to an end portion that is farthest from the substrate 102, from among end portions of each of a plurality of conductive pillars 150 in the vertical direction (e.g., Z direction), and each of the plurality of selectors 260 may be connected to an end portion that is closest to the substrate 102, from among the end portions of each of the plurality of conductive pillars 150 in the vertical direction (e.g., Z direction). Detailed configurations of the plurality of resistive layers 220 and the plurality of selectors 260 may substantially and respectively be the same as those of the plurality of resistive layers 120 and the plurality of selectors 160 described with reference to FIGS. 1, 2A, and 2B.

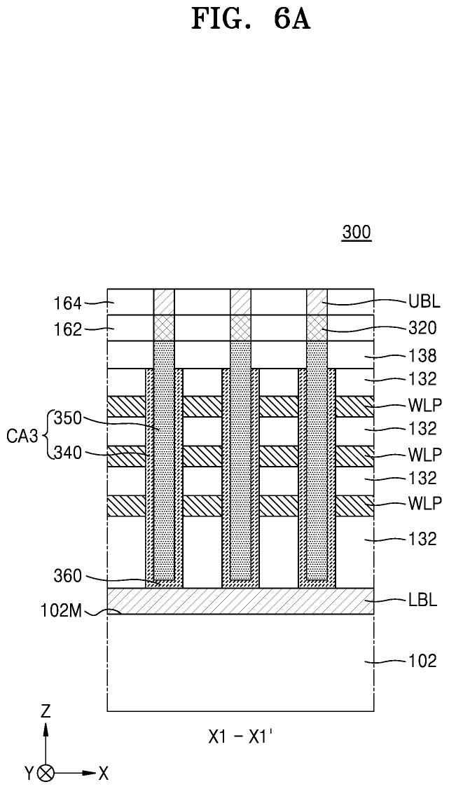

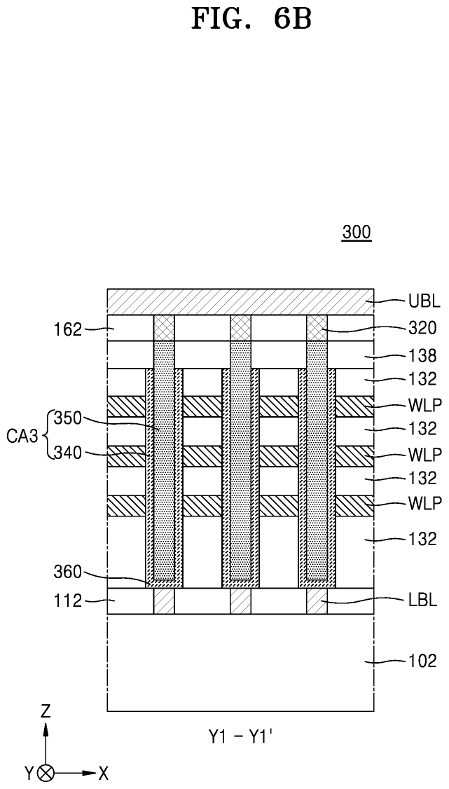

FIGS. 6A and 6B are cross-sectional views of a vertical memory device 300 according to embodiments of the present disclosure. FIG. 6A illustrates a cross-sectional configuration of a portion of the vertical memory device 300, which corresponds to a cross-section taken along line X1-X1′ of FIG. 1. FIG. 6B illustrates a cross-sectional configuration of a portion of the vertical memory device 300, which corresponds to a cross-section taken along line Y1-Y1′ of FIG. 1. In FIGS. 6A and 6B, the same reference numerals may be used to denote the same elements as in FIGS. 1 and 2A to 2C, and to the extent that an element has not been described herein, it may be assumed that the element is at least similar to a corresponding element that has been described elsewhere within the present disclosure.

Referring to FIGS. 6A and 6B, the vertical memory device 300 may substantially have the same configuration as the vertical memory device 100 described with reference to FIGS. 1 and 2A to 2C. However, the vertical memory device 300 may include a plurality of memory cell structures CA3, each of which includes a conductive pillar 350 and a cell variable resistive layer 340, and a plurality of selectors 360, each of which covers a bottom surface of the conductive pillar 350 included in each of the plurality of memory cell structures CA3. Each of the plurality of selectors 360 may be physically and integrally connected to the cell variable resistive layer 340 included in the memory cell structure CA3 corresponding thereto.

The vertical memory device 300 may further include a plurality of resistive layers 320 disposed between the memory cell structure CA3 and a plurality of second bit lines UBL. The plurality of resistive layers 320 may be spaced apart from a substrate 102 in a vertical direction (e.g., Z direction) with the plurality of memory cell structures CA3 disposed therebetween. Detailed configurations of the resistive layer 320, the cell variable resistive layer 340, the conductive pillar 350, and the selector 360 may substantially and respectively be the same as those of the resistive layer 120, the cell variable resistive layer 140, the conductive pillar 150, and the selector 160 described with reference to FIGS. 1 and 2A to 2C.

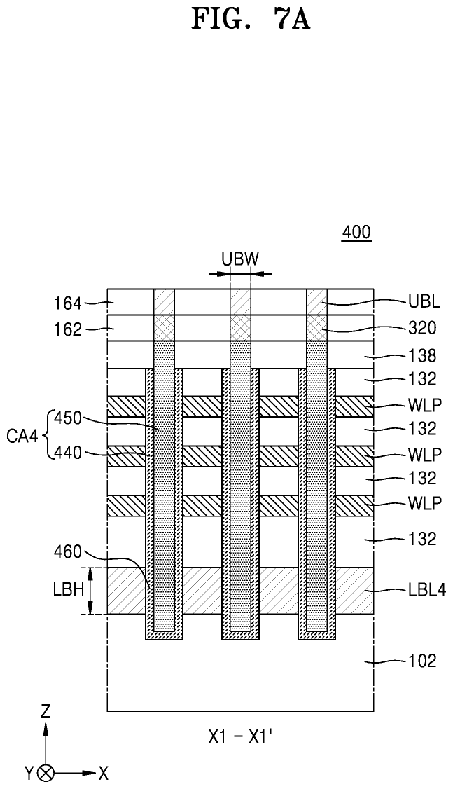

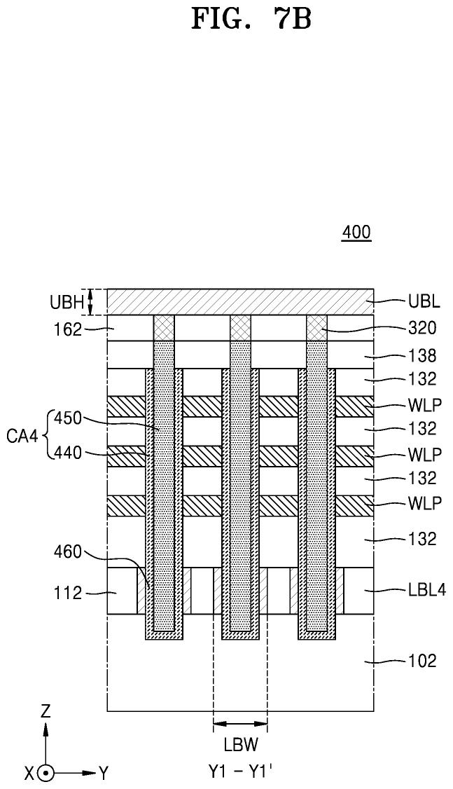

FIGS. 7A and 7B are cross-sectional views of a vertical memory device 400 according to embodiments of the present disclosure. FIG. 7A illustrates a cross-sectional configuration of a portion of the vertical memory device 400, which corresponds to a cross-section taken along line X1-X1′ of FIG. 1. FIG. 7B illustrates a cross-sectional configuration of a portion of the vertical memory device 400, which corresponds to a cross-section taken along line Y1-Y1′ of FIG. 1. In FIGS. 7A and 7B, the same reference numerals may be used to denote the same elements as in FIGS. 1, 2A to 2C, 6A, and 6B, and to the extent that an element has not been described herein, it may be assumed that the element is at least similar to a corresponding element that has been described elsewhere within the present disclosure.

Referring to FIGS. 7A and 7B, the vertical memory device 400 may substantially have the same configuration as the vertical memory device 300 described with reference to FIGS. 6A and 6B. However, the vertical memory device 400 may include a plurality of memory cell structures CA4, a plurality of selectors 460, and a plurality of first bit lines LBL4. Each of the plurality of memory cell structures CA4 may include a conductive pillar 450 and a cell variable resistive layer 440. Each of the plurality of selectors 460 may cover a bottom surface of the conductive pillar 450 included in each of the plurality of memory cell structures CA4. The plurality of first bit lines LBL4 may be respectively connected to the plurality of selectors 460. Each of the plurality of selectors 460 may be physically and integrally connected to the cell variable resistive layer 440 included in the memory cell structure CA4 corresponding thereto.

In the vertical memory device 400, the conductive pillar 450 and the selector 460 may pass through a selected one of the plurality of first bit lines LBL4 in a vertical direction (e.g., Z direction). The conductive pillar 450 and the selector 460 may completely pass through the first bit line LBL4 in the vertical direction (e.g., Z direction), and a bottom surface of each of the conductive pillar 450 and the selector 460 may be at a lower vertical level than a bottom surface of each of the plurality of first bit lines LBL4.

Each of the plurality of selectors 460 may be in contact with the bottom surface and a sidewall of the conductive pillar 450. In a portion of the conductive pillar 450, which is adjacent to a substrate 102 and the first bit line LBL4, the sidewall and the bottom surface of the conductive pillar 450 may be in contact with the selector 460 and be spaced apart from the first bit line LBL4 in a lateral direction (e.g., X direction and Y direction) with the selector 460 disposed therebetween.

A thickness LBH of each of the first bit lines LBL4 in the vertical direction (e.g., Z direction) may be greater than a thickness UBH of each of a plurality of second bit lines UBL in the vertical direction (e.g., Z direction). A minor-axis width LBW of each of the plurality of first bit lines LBL4 in a second lateral direction (e.g., Y direction) may be greater than a minor-axis width UBW of each of the plurality of second bit lines UBL in a first lateral direction (e.g., X direction).

Detailed configurations of the cell variable resistive layer 440, the conductive pillar 450, the selector 460, and the first bit line LBL4 may substantially and respectively be the same as those of the cell variable resistive layer 140, the conductive pillar 150, the selector 160, and the first bit line LBL described with reference to FIGS. 1 and 2A to 2C.

In the vertical memory device 400 described with reference to FIGS. 7A and 7B, a contact area disposed between the selector 460 and the conductive pillar 450 in the memory cell structure CA4 may be relatively great. Accordingly, capability to supply current to the conductive pillar 450 through the selector 460 may increase, and cyclic endurance according to the number of program and crase cycles may increase.

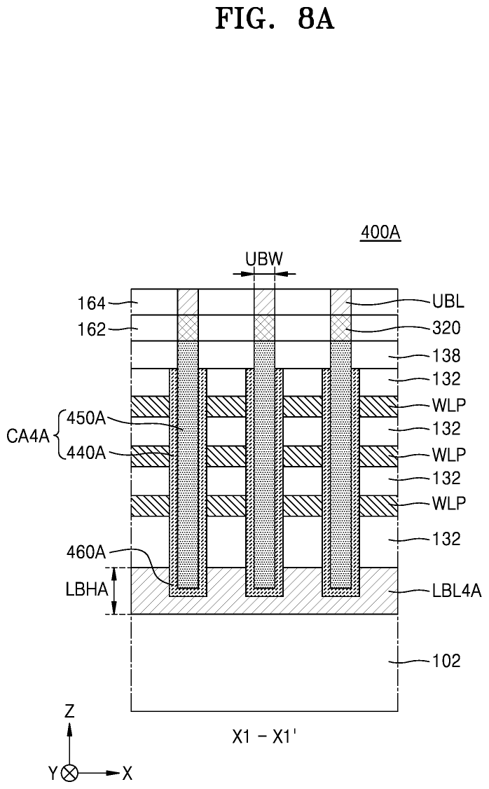

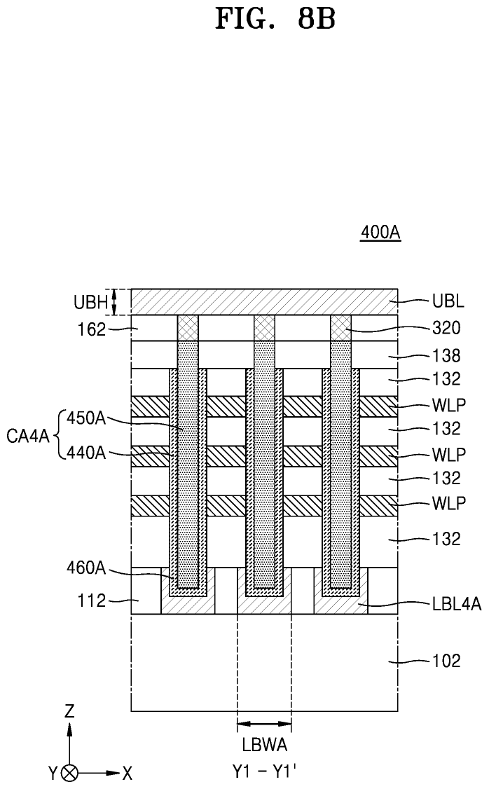

FIGS. 8A and 8B are cross-sectional views of a vertical memory device 400A according to embodiments of the present disclosure. FIG. 8A illustrates a cross-sectional configuration of a portion of the vertical memory device 400A, which corresponds to a cross-section taken along line X1-X1′ of FIG. 1. FIG. 8B illustrates a cross-sectional configuration of a portion of the vertical memory device 400A, which corresponds to a cross-section taken along line Y1-Y1′ of FIG. 1. In FIGS. 8A and 8B, the same reference numerals may be used to denote the same elements as in FIGS. 1, 2A to 2C, 6A, 6B, 7A, and 7B, and to the extent that an element has not been described herein, it may be assumed that the element is at least similar to a corresponding element that has been described elsewhere within the present disclosure.

Referring to FIGS. 8A and 8B, the vertical memory device 400A may substantially have the same configuration as the vertical memory device 400 described with reference to FIGS. 6A and 6B. However, the vertical memory device 400A may include a plurality of memory cell structures CA4A, a plurality of selectors 460A, and a plurality of first bit lines LBL4A. Each of the plurality of memory cell structures CA4A may include a conductive pillar 450A and a cell variable resistive layer 440A. Each of the plurality of selectors 460A may cover a bottom surface of the conductive pillar 450A included in each of the plurality of memory cell structures CA4A. The plurality of first bit lines LBL4A may be respectively connected to the plurality of selectors 460A. Each of the plurality of selectors 460A may be physically and integrally connected to the cell variable resistive layer 440A included in the memory cell structure CA4A corresponding thereto.

In the vertical memory device 400A, the conductive pillar 450A and the selector 460A may pass through a portion of a selected one of the plurality of first bit lines LBL4A in a vertical direction (e.g., Z direction). A bottom surface of each of the conductive pillar 450A and the selector 460A may be at a higher vertical level than a bottom surface of each of the plurality of first bit lines LBL4A.

Each of the plurality of selectors 460A may be in contact with the bottom surface and a sidewall of the conductive pillar 450A. In a portion of the conductive pillar 450A, which is adjacent to a substrate 102 and the first bit line LBL4A, the sidewall and the bottom surface of the conductive pillar 450A may be in contact with the selector 460A and be spaced apart from the first bit line LBL4A with the selector 460A disposed therebetween in a lateral direction (e.g., X direction and Y direction) and the vertical direction (e.g., Z direction).

A thickness LBHA of each of the first bit lines LBL4A in the vertical direction (e.g., Z direction) may be greater than a thickness UBH of each of a plurality of second bit lines UBL in the vertical direction (e.g., Z direction). A minor-axis width LBWA of each of the plurality of first bit lines LBL4A in a second lateral direction (e.g., Y direction) may be greater than a minor-axis width UBW of each of the plurality of second bit lines UBL in a first lateral direction (e.g., X direction).

Detailed configurations of the cell variable resistive layer 440A, the conductive pillar 450A, the selector 460A, and the first bit line LBL4A may substantially and respectively be the same as those of the cell variable resistive layer 140, the conductive pillar 150, the selector 160, and the first bit line LBL described with reference to FIGS. 1 and 2A to 2C.

In the vertical memory device 400A described with reference to FIGS. 8A and 8B, a contact area disposed between the selector 460A and the conductive pillar 450A in the memory cell structure CA4A may be relatively great. Accordingly, capability to supply current to the conductive pillar 450A through the selector 460A may increase, and cyclic endurance may increase. In addition, in the memory cell structure CA4A, the selector 460A may at least partially surround a lower sidewall and the bottom surface of the conductive pillar 450A, and the first bit line LBL4A may at least partially surround a lower sidewall and the bottom surface of the selector 460A. Thus, not only the contact area disposed between the selector 460A and the conductive pillar 450A but also a contact area disposed between the first bit line LBL4A and the selector 460A may be relatively great. Therefore, capability to supply current to the conductive pillar 450A through the first bit line LBL4A and the selector 460A may further increase, and cyclic endurance may further increase.

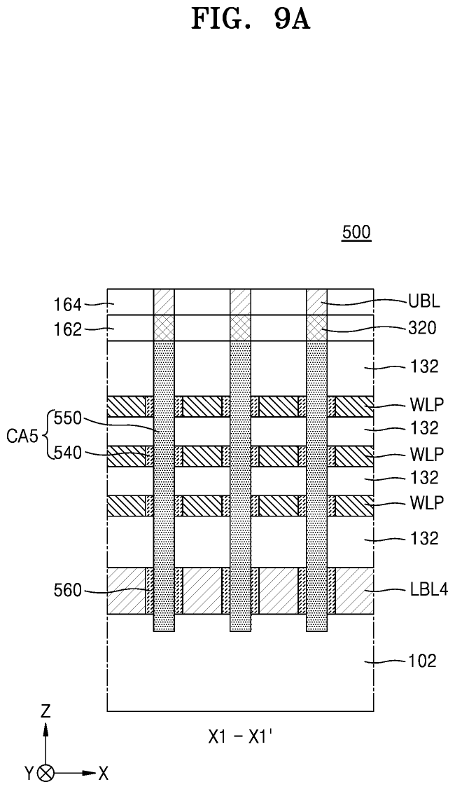

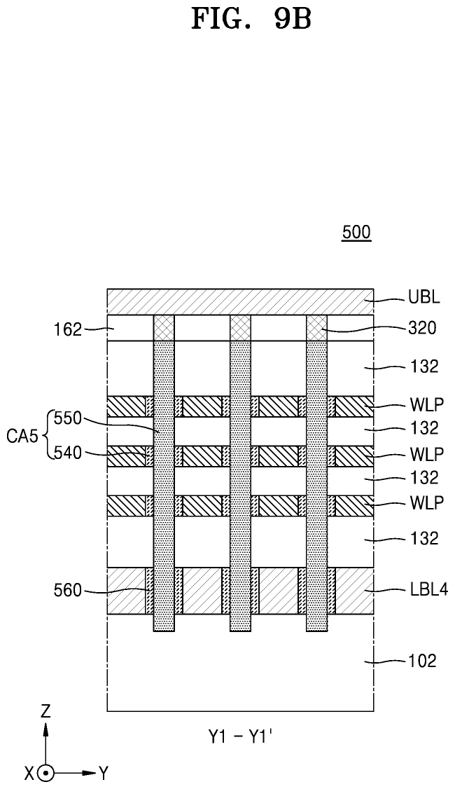

FIGS. 9A and 9B are cross-sectional views of a vertical memory device 500 according to embodiments of the present disclosure. FIG. 9A illustrates a cross-sectional configuration of a portion of the vertical memory device 500, which corresponds to a cross-section taken along line X1-X1′ of FIG. 1. FIG. 9B illustrates a cross-sectional configuration of a portion of the vertical memory device 500, which corresponds to a cross-section taken along line Y1-Y1′ of FIG. 1. In FIGS. 9A and 9B, the same reference numerals may be used to denote the same elements as in FIGS. 1, 2A to 2C, 7A, and 7B, and to the extent that an element has not been described herein, it may be assumed that the element is at least similar to a corresponding element that has been described elsewhere within the present disclosure.

Referring to FIGS. 9A and 9B, the vertical memory device 500 may substantially have the same configuration as the vertical memory device 400 described with reference to FIGS. 7A and 7B. However, the vertical memory device 500 may include a plurality of memory cell structures CA5. Each of the plurality of memory cell structures CA5 may include a conductive pillar 550 and a plurality of cell variable resistive layers 540 at least partially surrounding the conductive pillar 550.

Each of the plurality of cell variable resistive layers 540 included in one memory cell structure CA5 may be disposed between the conductive pillar 550 and a selected one of a plurality of word line plates WLP. In one memory cell structure CA5, the plurality of cell variable resistive layers 540 may overlap each other and be spaced apart from each other in a vertical direction (e.g., Z direction). Each of the plurality of cell variable resistive layers 540 may be in contact with a sidewall of a selected one of the plurality of word line plates WLP and a sidewall of the conductive pillar 550.

From among the plurality of isolation insulating films 132, some isolation insulating film 132 may be disposed between two adjacent ones of the plurality of cell variable resistive layers 540 in the vertical direction (e.g., Z direction) and overlap the plurality of cell variable resistive layers 540 in the vertical direction (e.g., Z direction).

The vertical memory device 500 may include a plurality of selectors 560 connected to the conductive pillar 550 included in each of the plurality of memory cell structures CA5. Each of the plurality of cell variable resistive layers 540 included in one memory cell structure CA5 may be physically spaced apart from the selector 560 connected to the conductive pillar 550 included in the one memory cell structure CA5. The plurality of cell variable resistive layers 540 and the selector 560, which are connected to one conductive pillar 550, may overlap each other and be spaced apart from each other in the vertical direction (e.g., Z direction).

Each of a plurality of conductive pillars 550 and the plurality of selectors 560 may pass through a selected one of a plurality of first bit lines LBL4 in the vertical direction (e.g., Z direction). The conductive pillar 550 and the selector 560 may completely pass through the first bit line LBL4 in the vertical direction (e.g., Z direction). A bottom surface of the conductive pillar 550 may be at a lower vertical level than a bottom surface of each of the plurality of first bit lines LBL4. The bottom surface of the conductive pillar 550 may be at a lower vertical level than a bottom surface of the selector 560. The bottom surface of the selector 560 may substantially be at the same vertical level as the bottom surface of each of the plurality of first bit lines LBL4. A top surface of the selector 560 may substantially be at the same vertical level as a top surface of each of the plurality of first bit lines LBL4.

Detailed configurations of the cell variable resistive layer 540, the conductive pillar 550, the selector 560, and the first bit line LBL4 may substantially and respectively be the same as those of the cell variable resistive layer 140, the conductive pillar 150, the selector 160, and the first bit line LBL described with reference to FIGS. 1 and 2A to 2C.

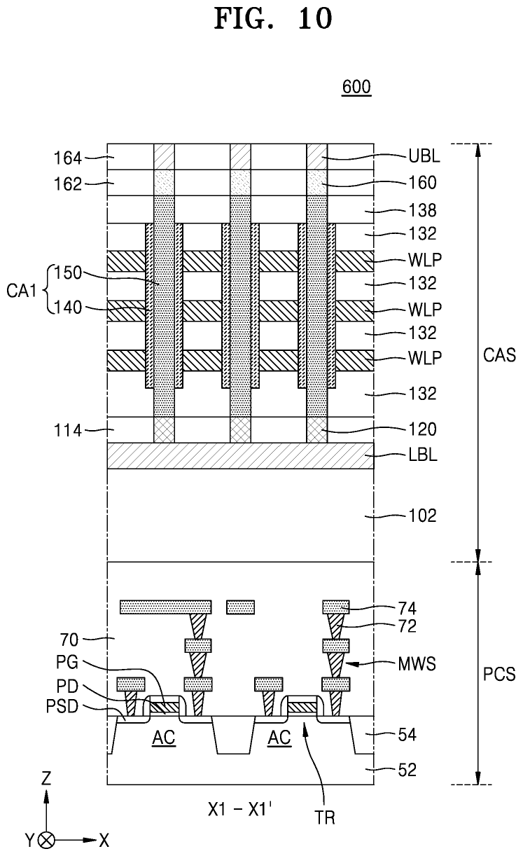

FIG. 10 is a cross-sectional view of a vertical memory device 600 according to embodiments of the present disclosure. FIG. 10 illustrates a cross-sectional configuration of a portion of the vertical memory device 600, which corresponds to a cross-section taken along line X1-X1′ of FIG. 1. In FIG. 10, the same reference numerals may be used to denote the same elements as in FIGS. 1 and 2A to 2C, and to the extent that an element has not been described herein, it may be assumed that the element is at least similar to a corresponding element that has been described elsewhere within the present disclosure.

Referring to FIG. 10, the vertical memory device 600 may substantially have the same configuration as the vertical memory device 100 described with reference to FIGS. 1 and 2A to 2C. However, the vertical memory device 600 may include a cell array structure CAS and a peripheral circuit structure PCS, which overlap each other in a vertical direction (e.g., Z direction). The cell array structure CAS may include components described with reference to FIGS. 1 and 2A to 2C. The peripheral circuit structure PCS may be spaced apart from the plurality of memory cell structures CA1 in a vertical direction (e.g., Z direction) with a substrate 102 disposed therebetween.

The peripheral circuit structure PCS may include a substrate 52, a plurality of circuits formed on the substrate 52, and a multilayered wiring structure MWS configured to connect the plurality of circuits to each other or connect the plurality of circuits to components of the cell array structure CAS.

The substrate 52 may include a semiconductor substrate. For example, the substrate 52 may include silicon (Si), germanium (Ge), or silicon germanium (SiGe). An active region AC may be defined by a device isolation film 54 in the substrate 52. A plurality of transistors TR constituting the plurality of circuits may be formed on the active region AC. Each of the plurality of transistors TR may include a gate dielectric film PD and a gate PG, which are sequentially stacked on the substrate 52, and a plurality of ion implantation regions PSD formed on both sides of the gate PG in the active region AC. Each of the plurality of ion implantation regions PSD may constitute a source region or a drain region of the transistor TR.

The multilayered wiring structure MWS in the peripheral circuit structure PCS may include a plurality of contact plugs 72 and a plurality of conductive lines 74. At least some of the plurality of conductive lines 74 may be electrically connectable to the transistor TR. The plurality of contact plugs 72 may connect the plurality of transistors TR to selected some of the plurality of conductive lines 74. The plurality of transistors TR and the multilayered wiring structure MWS which are in the peripheral circuit structure PCS, may be covered by an interlayer insulating film 70. The interlayer insulating film 70 may include a silicon oxide film, a silicon nitride film, a silicon oxynitride (SiON) film, a silicon oxycarbonitride (SiOCN) film, or a combination thereof.

In the peripheral circuit structure PCS, the plurality of transistors TR, the plurality of contact plugs 72, and the plurality of conductive lines 74 may constitute various circuits. Each of the plurality of transistors TR may be electrically connectable to a memory cell region MEC through a plurality of multilayered wiring structures MWS.

In embodiments, like the vertical memory device 100A described with reference to FIG. 3, the cell array structure CAS may include a plurality of first contact structures LBC connected to a plurality of first bit lines LBL, a plurality of second contact structures UBC connected to a plurality of second bit lines UBL, and a plurality of third contact structures WLC connected to a plurality of word line plates WLP. The plurality of first contact structures LBC, the plurality of second contact structures UBC, and the plurality of third contact structures WLC shown in FIG. 3 may be each connected to the plurality of circuits included in the peripheral circuit structure PCS. A driving voltage may be independently applied from the peripheral circuit structure PCS to each of the plurality of first bit lines LBL, the plurality of second bit lines UBL, and the plurality of word line plates WLP included in the cell array structure CAS through the plurality of first contact structures LBC, the plurality of second contact structures UBC, and the plurality of third contact structures WLC shown in FIG. 3.

FIG. 10 illustrates a configuration in which the peripheral circuit structure PCS is under the cell array structure CAS in the vertical direction (e.g., Z direction), but the inventive concept is not necessarily limited thereto. For example, the peripheral circuit structure PCS and the cell array structure CAS may form a chip-to-chip (C2C) structure. The formation of the C2C structure may include forming the cell array structure CAS on a first wafer, forming the peripheral circuit structure PCS on a second wafer that is different from the first wafer, and connecting the cell array structure CAS and the peripheral circuit structure PCS to each other by using a bonding technique. In this case, the peripheral circuit structure PCS may overlap the cell array structure CAS on the cell array structure CAS in the vertical direction (e.g., Z direction), and the peripheral circuit structure PCS may be spaced apart from the memory cell structure CA1 in the vertical direction (e.g., Z direction) with the plurality of second bit lines UBL and a plurality of selectors 160 disposed therebetween.

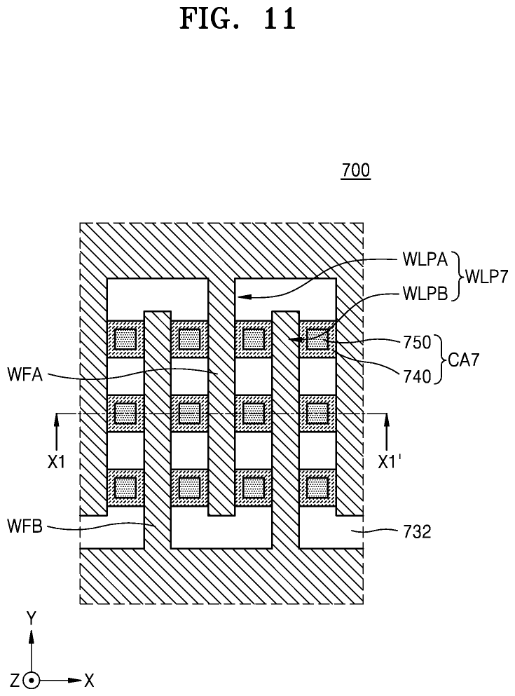

FIG. 11 is a plan view of some components of a vertical memory device 700 according to embodiments of the present disclosure. In FIG. 11, the same reference numerals may be used to denote the same elements as in FIGS. 1 and 2A to 2C, and to the extent that an element has not been described herein, it may be assumed that the element is at least similar to a corresponding element that has been described elsewhere within the present disclosure.

Referring to FIG. 11, the vertical memory device 700 may substantially have the same configuration as the vertical memory device 100 described with reference to FIGS. 1 and 2A to 2C. In particular, in FIG. 11, a cross-sectional configuration taken along line X1-X1′ may substantially be the same as that described with reference to FIGS. 2A and 2B. However, the vertical memory device 700 may include a word line plate WLP7 instead of the word line plate WLP of the vertical memory device 100.

The word line plate WLP7 may include a first local word line plate WLPA and a second local word line plate WLPB, which are spaced apart from each other in a lateral direction (or Y direction in FIG. 11) and are at the same vertical direction. A space between the first local word line plate WLPA and the second local word line plate WLPB may be filled by an insulating pattern 732. The insulating pattern 732 may include a silicon oxide film, a silicon nitride film, or a combination thereof, without necessarily being limited thereto.

The first local word line plate WLPA and the second local word line plate WLPB may each have a comb shape including a plurality of protrusion electrode portions WFA and WFB constituting interdigitated electrodes.

The vertical memory device 700 may include a plurality of memory cell structures CA7, which may pass through the insulating pattern 732 in a vertical direction (e.g., Z direction) between the protrusion electrode portion WFA of the first local word line plate WLPA and the protrusion electrode portion WFB of the second local word line plate WLPB. Each of the plurality of memory cell structures CA7 may include a conductive pillar 750 and a cell variable resistive layer 740. In each of the plurality of memory cell structures CA7, the conductive pillar 750 may be spaced apart from each of the first local word line plate WLPA and the second local word line plate WLPB, and the cell variable resistive layer 740 may at least partially surround the conductive pillar 750 and be in contact with each of the first local word line plate WLPA and the second local word line plate WLPB. Detailed configurations of the word line plate WLP7, the cell variable resistive layer 740, and the conductive pillar 750 may substantially and respectively be the same as those of the word line plate WLP, the cell variable resistive layer 140, and the conductive pillar 150 described with reference to FIGS. 1 and 2A to 2C.

FIG. 11 illustrates an example in which the plurality of memory cell structures CA7 are arranged in a matrix form in a first lateral direction (e.g., X direction) and a second lateral direction (e.g., Y direction) in a view from above (on an X-Y plane), but the inventive concept is not necessarily limited thereto. For example, in the view from above (on the X-Y plane), the plurality of memory cell structures CA7 may be arranged in a hexagonal array. In addition, a planar shape of each of the first local word line plate WLPA and the second local word line plate WLPB in the word line plate WLP7 is not necessarily limited to that shown in FIG. 11 and may be variously modified and changed as needed. For example, as shown in FIG. 11, in the view from above (on the X-Y plane), each of the plurality of protrusion electrode portions WFA and WFB included in the first local word line plate WLPA and the second local word line plate WLPB is not necessarily limited to having a rectangular shape extending primarily in the second lateral direction (e.g., Y direction). For example, each of the plurality of protrusion electrode portions WFA and WFB may independently have a shape extending nonlinearly, such as a curved shape or a zigzag shape, in a lengthwise direction thereof or have a structure of which a width in the first lateral direction (e.g., X direction) is variable in the lengthwise direction thereof.

The vertical memory device 200, 300, 400, 400A, 500, 600, and 700 described with reference to FIGS. 5A to 11 may substantially provide the same effects as those of the vertical memory device 100 and 100A described with reference to FIGS. 1 to 3.

Next, examples of operations of a vertical memory device according to the inventive concept are described. Although the structure of the vertical memory device 100 described with reference to FIGS. 1 and 2A to 2C is described as an example in the following description, the above descriptions may be wholly applied to the structures of the vertical memory devices 100A, 100B, 200, 300, 400, 400A, 500, 600, and 700 described with reference to FIGS. 3 to 11.

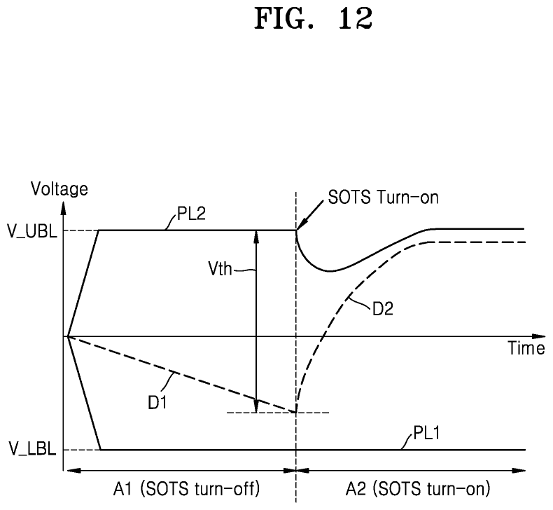

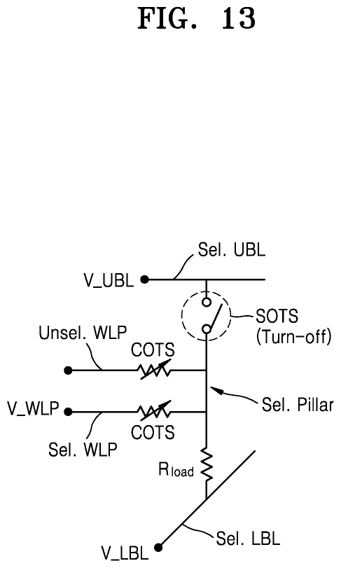

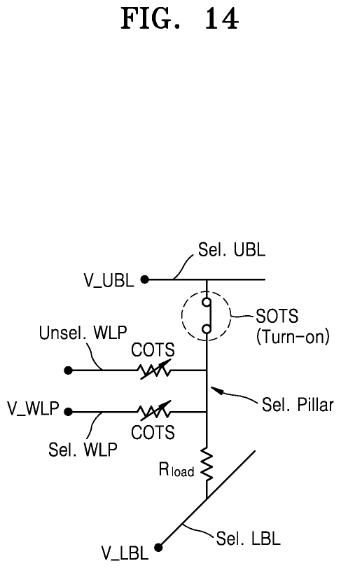

FIG. 12 is a diagram illustrating a voltage change in each of a first section A1 and a second section A2 in a vertical memory device according to embodiments of the present disclosure. Here, the first section A1 refers to a turn-off section of a selector 160 (hereinafter, also referred to as an “OTS selector SOTS”) including an OTS material, and the second section A2 refers to a turn-on section of the OTS selector SOTS. FIG. 13 is a circuit diagram illustrating a turn-off state of an OTS selector SOTS in a vertical memory device including the OTS selector SOTS, according to embodiments of the present disclosure. FIG. 14 is a circuit diagram illustrating a turn-on state of an OTS selector SOTS in a vertical memory device including the OTS selector SOTS, according to embodiments of the present disclosure.

Referring to FIGS. 12 to 14, in the vertical memory device 100 described with reference to FIGS. 1 and 2A to 2C, one first bit line LBL and one second bit line UBL is assumed to be selected, a voltage V_LBL is assumed to be applied to a selected first bit line LBL (hereinafter, referred to as Sel. LBL), a voltage V_UBL is assumed to be applied to a selected second bit line UBL (hereinafter, referred to as Sel. UBL), and an unselected voltage (e.g., 0V) is assumed to be applied to each of an unselected first bit line LBL (hereinafter, referred to as Unsel. LBL) and an unselected second bit line UBL (hereinafter, referred to as Unsel. UBL). Here, a voltage drop due to a wiring resistance is not considered for brevity. In addition, a resistance of the OTS selector SOTS and a resistance of the resistive layer 120 are assumed to have a relationship that satisfies Equation 1:

$$R\_off > R\_load > R\_on \qquad [ Equation 1 ]$$

In Equation 1, R_off is a resistance of the OTS selector SOTS in a turn-off state, R_load is a resistance of the resistive layer 120, and R_on is a resistance of the OTS selector SOTS in the turn-on state.

When a threshold voltage Vth or higher is applied to both ends of the OTS selector SOTS, the resistance of the OTS selector SOTS may be rapidly reduced due to an electronic transition phenomenon, which is called threshold switching, thereby causing a turn-on state in which current flows through the OTS selector SOTS. When current of a specific threshold value Ihold or less flows through the OTS selector SOTS that is in the turn-on state, the resistance of the OTS selector SOTS may rapidly increase again, thereby causing a turn-off state in which current hardly flows through the OTS selector SOTS.

A target cell access method of a random access type in a memory device having a cross-point array structure is described as follows. Here, an example in which a plurality of cell variable resistive layers 140 included in the vertical memory device 100 include am OTS material is described. To access (read/write) a cell variable resistive layer 140 (hereinafter, COTS) of one target memory cell disposed between one selected word line plate WLP (hereinafter, referred to as Sel. WLP) and one selected conductive pillar 150 (hereinafter, referred to as Sel. Pillar), an operating voltage (e.g., an operating voltage of V0) may need to be applied to only the one target memory cell. The operating voltage V0 may be divided and applied to the Sel. WLP and the Sel. Pillar, and thus, only the one target memory cell may operate. For example, an operating voltage of −(½) V0 may be applied to the Sel. WLP, an operating voltage of +(½) V0 may be applied to the Sel. Pillar. Accordingly, the operating voltage may be applied to the one target memory cell, and only a voltage (e.g. +(½) V0) that is much lower than the operating voltage may be applied to remaining memory cells other than the on target memory cell in the Sel. Pillar, and thus, only the one target memory cell may operate. For example, an appropriate level of voltage (e.g., (½) V0) may be applied to the one target memory cell to access the one target memory cell.

Next, a method of applying a desired voltage (e.g., (½) V0) to only a selected conductive pillar (or Sel. Pillar), from among a plurality of conductive pillars, by using an OTS selector SOTS, according to the inventive concept, is described.

As shown in FIGS. 12 to 14, when a voltage V_LBL and a voltage V_UBL are respectively applied to a selected first bit line Sel. LBL and a selected second bit line Sel. UBL, a voltage difference may occur between the selected first bit line Sel. LBL and the selected second bit line Sel. UBL. For example, when V_UBL equals +(½) V0 and V_LBL equals −V1, a voltage of V_UBL-V_LBL (ΔV) may be applied to the OTS selector SOTS disposed between the Sel. UBL and the Sel. LBL, the Sel. Pillar, and the resistive layer 120. In FIG. 12, a solid line indicated by PL1 denotes a potential of the Sel. LBL, and a solid line indicated by PL2 denotes a potential of the Sel. UBL. As in the first section A1 of FIG. 12, because a resistance of the OTS selector SOTS is much higher than a resistance of the resistive layer 120 in the turn-off state of the OTS selector SOTS, most of a bias may be applied to the OTS selector SOTS. For example, the potential of the Sel. Pillar may gradually approach the voltage V_LBL. In this case, it may take some time for the potential of the Sel. Pillar to approach the voltage V_LBL due to an RC delay caused by a resistance difference in an electrical connection path. In FIG. 12, a dashed line indicated by D1 denotes a potential change at the bottom of the OTS selector SOTS in the Sel. Pillar.

As in the second section A2 of FIG. 12, when the potential of the Sel. Pillar sufficiently approaches the voltage V_LBL and a bias higher than a threshold voltage Vth is applied to both ends of the OTS selector SOTS, the OTS selector SOTS may be turned on. To this end, a threshold voltage Vth of the OTS selector SOTS may be lower than a voltage difference ΔV between the voltage V_UBL and the voltage V_LBL. In this case, when the resistance of the OTS selector SOTS is rapidly reduced, most of the bias may be applied to the resistive layer 120. In this case, the potential of the Sel. Pillar may become equal or similar to the voltage of V_UBL. In FIG. 12, a dashed line indicated by D2 denotes a process in which the Sel. Pillar reaches a desired voltage V_UBL after the OTS selector SOTS is turned on. In the above-described process, the voltage V_UBL may be transmitted to the Sel. Pillar.

In embodiments, a voltage drop of a predetermined level (e.g., Vhold) may occur even in the OTS selector SOTS that is in the turn-on state. In this case, before the OTS selector SOTS is turned on or at a time point after the OTS selector SOTS is turned on, the voltage drop may be compensated for by increasing the voltage V_UBL by Vhold. In the present embodiment, for brevity, the voltage drop is assumed to be compensated for, and effects of the voltage drop are not considered.

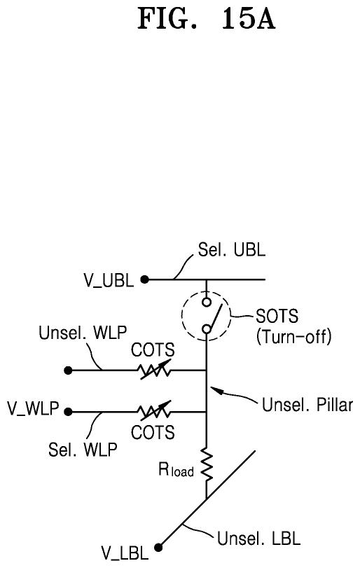

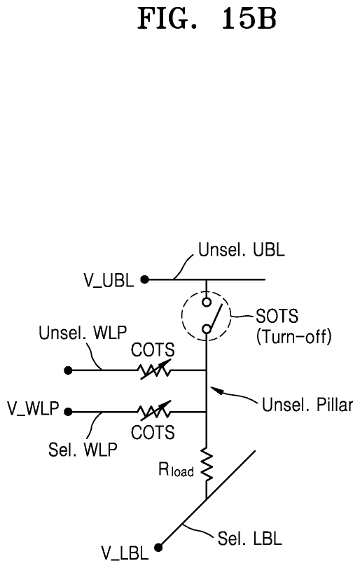

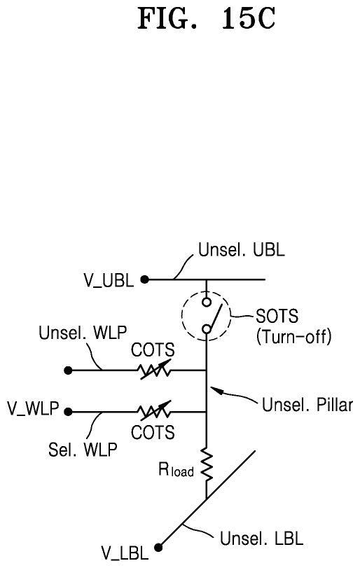

FIGS. 15A, 15B, and 15C are circuit diagrams each illustrating voltage behavior of an unselected conductive pillar (hereinafter, referred to as Unsel. Pillar) in a vertical memory device including an OTS selector SOTS, according to embodiments of the present disclosure.

As shown in FIG. 15A, a voltage V_UBL (e.g., +(½) V0) may be applied to a Sel. UBL, an unselected voltage (e.g., 0V) may be applied to an Unsel. LBL, a voltage of −(½) V0 may be applied to a selected word line plate (or Sel. WLP), and an unselected voltage (e.g., 0V) may be applied to an unselected word line plate (or Unsel. WLP). In this case, the OTS selector SOTS may remain turned off, and a potential of the Unsel. Pillar may reach a voltage (e.g., 0V) of the Unsel. LBL. Thus, a potential of the cell variable resistive layer COTS included in the Unsel. Pillar may gradually approach the unselected voltage (e.g., 0V) applied to the Unsel. LBP, and a memory cell included in the Unsel. Pillar may remain idle.

As shown in FIG. 15B, an unselected voltage (e.g., 0V) may be applied to an Unsel. UBL, a voltage V_LBL (e.g. −V1) may be applied to a Sel. LBL, a voltage of +(½) V0 may be applied to the Sel. WLP, and a voltage of +(½) V0 may be applied to the Unsel. WLP. In this case, the OTS selector SOTS may remain turned off, and a potential of the Unsel. Pillar may reach a potential of the Sel. LBL, and thus, the memory cell included in the Unsel. Pillar may remain idle.

As shown in FIG. 15C, an unselected voltage (e.g., 0V) may be applied to the Unsel. UBL, an unselected voltage (e.g., 0V) may be applied to the Unsel. LBL, a voltage of −(½) V0 may be applied to the Sel. WLP, and an unselected voltage (e.g., 0V) may be applied to the Unsel. WLP. In this case, the OTS selector SOTS may remain turned off, and a potential of the Unsel. Pillar may reach a voltage (e.g., 0V) of the Unsel. LBL, and thus, the memory cell included in the Unsel. Pillar may remain idle.

In embodiments, in each of the cases described with reference to FIGS. 15A, 15B, and 15C, to maintain the OTS selector SOTS in a turn-off state, a threshold voltage Vth of the OTS selector SOTS may be set to be lower than the voltage V_UBL (e.g., (½) V0) of the Sel. UBL and lower than the voltage V_LBL (e.g., −V1) of the Sel. LBL. For example, a range of the threshold voltage Vth of the OTS selector SOTS may be set to satisfy the conditions of Equations 2 and 3, or each of voltages of a second bit line UBL and a first bit line LBL may be set to satisfy both the conditions of Equations 2 and 3:

$$\vert Sel . V\_UBL \vert < ( Vth of SOTS ) < \vert Sel . V\_UBL - Sel . V\_LBL \vert \qquad [ Equation 2 ]$$

$$\vert Sel . V\_LBL \vert < ( Vth of SOTS ) < \vert Sel . V\_UBL - Sel . V\_LBL \vert \qquad [ Equation 3 ]$$

For example, when V_UBL equals (½) V0 and V_LBL equals −V1, the threshold voltage Vth, the voltage V_UBL, and the voltage V_LBL may be set to satisfy the following conditions:

$$\vert 1 / 2 V 0 \vert < Vth < \vert ( 1 / 2 ) V 0 + V 1 \vert , and \\ \vert - V 1 \vert < Vth < \vert ( 1 / 2 ) V 0 + V 1 \vert$$

Summarizing the above descriptions, in Case 1 in which the OTS selector SOTS is turned on as described with reference to FIG. 14 and each of Case 2, Case 3, and Case 4 in which the OTS selector SOTS is turned off as described with reference to each of FIGS. 15A, 15B, and 15C, combinations of the respective voltages of the first and second bit lines LBL and UBL may be set to select a target conductive pillar, for example, only a conductive pillar 150 connected to the Sel. LBL and the Sel. UBL. In addition, considering a voltage of the word line plate WLP, a combination of a voltage of the conductive pillar 150 and a voltage of the word line plate WLP may be set to operate a target cell, for example, only a cell connected to a selected conductive pillar 150 and a selected word line plate WLP.

Table 1 illustrates combinations of combinations of the voltage V_LBL of the first bit line LBL, the voltage V_UBL of the second bit line UBL, and a voltage V_WLP of the word line plate WLP in each of Case 1, Case 2, Case 3, and Case 4. Table 2 illustrates a bias (or SOTS bias) (V_UBL-V_LBL) of the OTS selector SOTS, a state (or SOTS state) of the OTS selector SOTS, a voltage V_Pillar of the conductive pillar 150, a bias (or COTS bias) (V_Pillar-V_WLP) of the cell variable resistive layer COTS, and a state (COTS state) of the cell variable resistive layer COTS, which may be obtained in each of Case 1, Case 2, Case 3, and Case 4.

TABLE 1

| | V_LBL | V_UBL | V_WLP |
|---|---|---|---|
| Case 1 | −V1 | +(1/2)V0 | −(1/2)V0 |
| | −V1 | +(1/2)V0 | 0 |
| Case 2 | 0 | +(1/2)V0 | −(1/2)V0 |
| | 0 | +(1/2)V0 | 0 |
| Case 3 | −V1 | 0 | −(1/2)V0 |
| | −V1 | 0 | 0 |
| Case 4 | 0 | 0 | −(1/2)V0 |
| | 0 | 0 | 0 |

TABLE 2

| | | SOTS | | COTS | COTS |
|---|---|---|---|---|---|
| Example | SOTS bias | state | V_Pillar | bias | state |
| Case 1 | (1/2)V0 + V1 | ON | +(1/2)V0 | V0 | operating |
| | (1/2)V0 + V1 | ON | +(1/2)V0 | (1/2)V0 | idle |
| Case 2 | (1/2)V0 | OFF | 0 | (1/2)V0 | idle |
| | (1/2)V0 | OFF | 0 | 0 | idle |
| Case 3 | −V1 | OFF | +(1/2)V0 | 0 | idle |
| | −V1 | OFF | +(1/2)V0 | (1/2)V0 | idle |
| Case 4 | 0 | OFF | 0 | (1/2)V0 | idle |
| | 0 | OFF | 0 | 0 | idle |

In embodiments, a bipolar operation may be required for a cell operation of the vertical memory device according to the embodiments. For example, a negative voltage (e.g., −V0) may be applied to the cell variable resistive layer COTS. In this case, an applied voltage may be applied to each of the first bit line LBL, the second bit line UBL, and the word line plate WLP by changing a plus or minus sign of the applied voltage to an opposite sign of an applied voltage in the operating state in Case 1 of Table 2, and thus, the cell variable resistive layer COTS may operate.

Next, methods of manufacturing a vertical memory device, according to embodiments of the present disclosure, are described in detail.

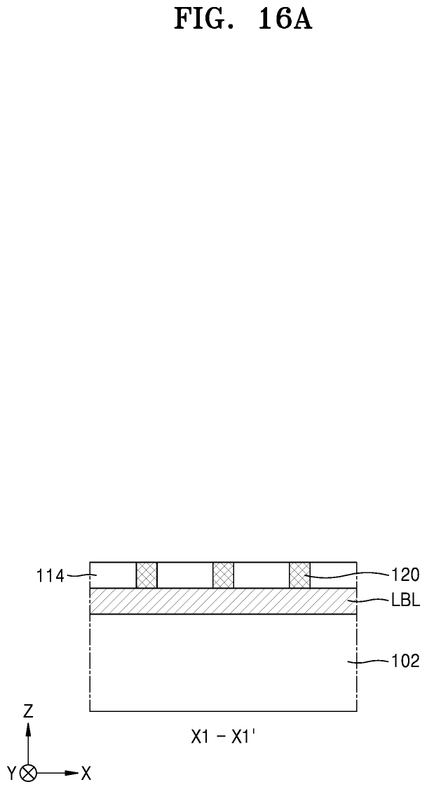

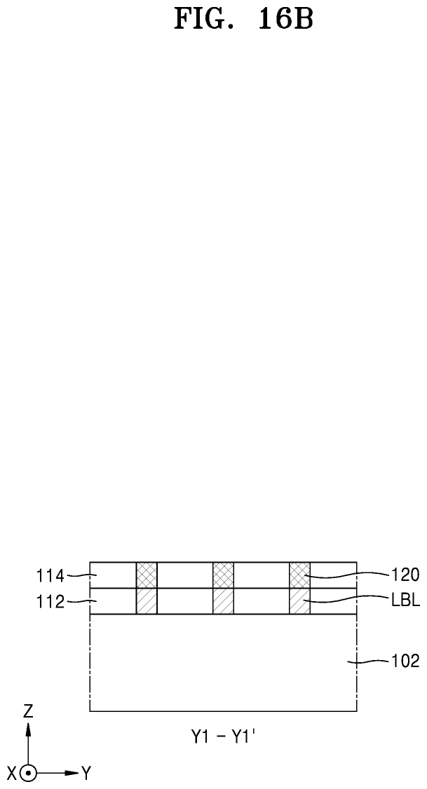

FIGS. 16A to 26B are cross-sectional views illustrating a method of manufacturing a vertical memory device, according to embodiments of the present disclosure. FIGS. 16A, 17A, 18A, 19A, 20A, 21A, 22A, 23A, 24A, 25A, and 26A are cross-sectional views of a portion corresponding to a cross-section taken along line X1-X1′ of FIG. 1, according to a process sequence, and FIGS. 16B, 17B, 18B, 19B, 20B, 21B, 22B, 23B, 24B, 25B, and 26B are cross-sectional views of a portion corresponding to a cross-section taken along line Y1-Y1′ of FIG. 1, according to a process sequence. An example of a method of manufacturing the vertical memory device 100 shown in FIGS. 1 and 2A to 2C is described with reference to FIGS. 16A to 26B. In FIGS. 16A to 26B, the same reference numerals may be used to denote the same elements as in FIGS. 1 and 2A to 2C, and to the extent that an element has not been described herein, it may be assumed that the element is at least similar to a corresponding element that has been described elsewhere within the present disclosure.

Referring to FIGS. 16A and 16B, a plurality of first bit lines LBL and a plurality of first insulating patterns 112 may be formed on a substrate 102. The plurality of first insulating patterns 112 may fill respective spaces between the plurality of first bit lines LBL. Thereafter, a plurality of resistive layers 120 may be formed on the plurality of first bit lines LBL, and a space between two adjacent ones of the plurality of resistive layers 120 may be filled by a first insulating plate 114.

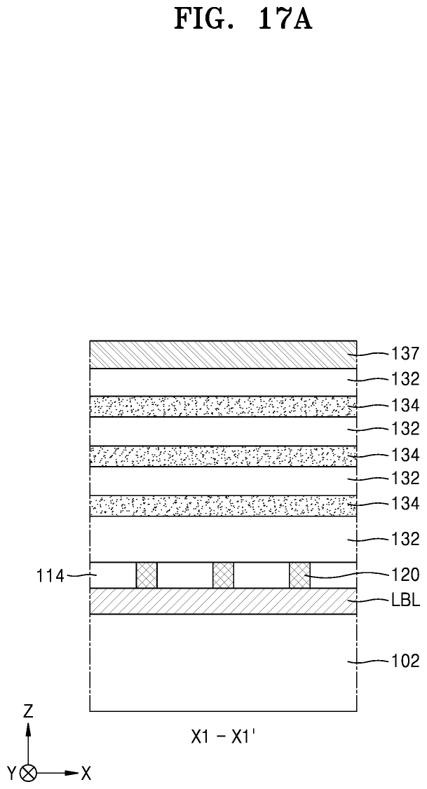

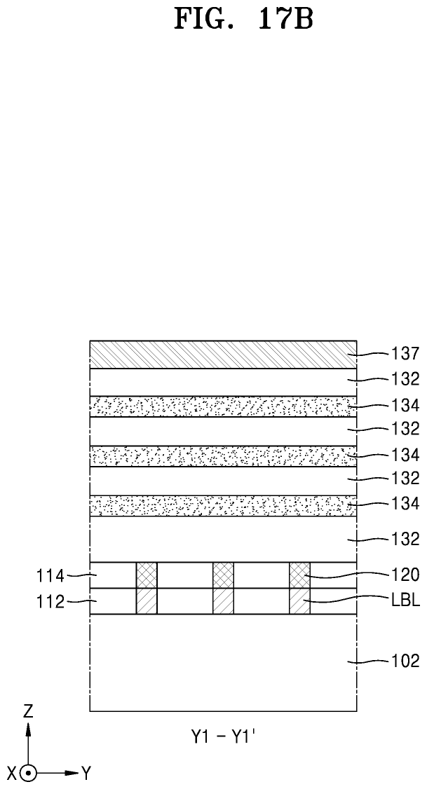

Referring to FIGS. 17A and 17B, a plurality of isolation insulating films 132 and a plurality of sacrificial insulating films 134 may be alternately stacked one-by-one on the plurality of resistive layers 120 and the first insulating plate 114. Thereafter, a top sacrificial insulating film 137 may be formed on an uppermost one of the plurality of isolation insulating films 132. A lowest one of the isolation insulating films 132, which is closest to the substrate 102, may have a greater thickness than other isolation insulating films 132 in a vertical direction (e.g., Z direction). In embodiments, the plurality of isolation insulating films 132 may include a silicon oxide film, and each of a plurality of sacrificial insulating films 134 and the top sacrificial insulating film 137 may include a silicon nitride film.

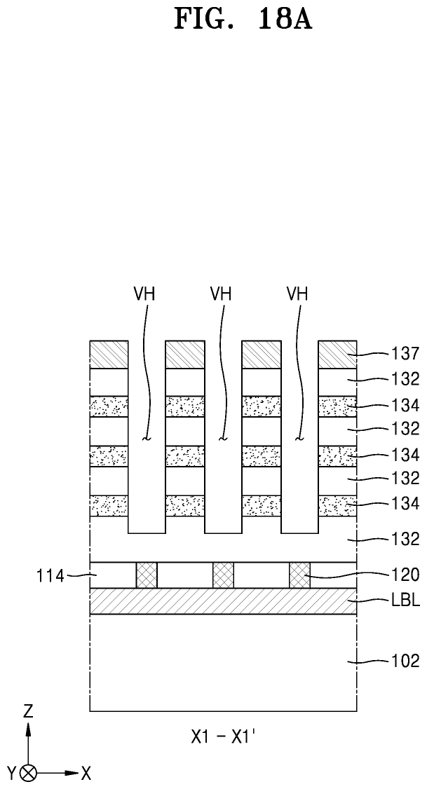

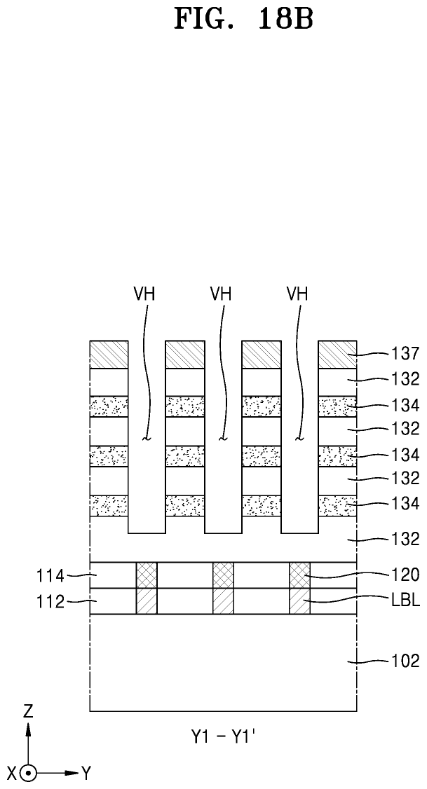

Referring to FIGS. 18A and 18B, respective partial regions of the top sacrificial insulating film 137, the plurality of isolation insulating films 132, and the plurality of sacrificial insulating films 134 may be etched from a top surface of the top sacrificial insulating film 137, and thus, a plurality of vertical holes VH may be formed. A lowermost one of the isolation insulating films 132 may be exposed at bottom surfaces of the plurality of vertical holes VH.

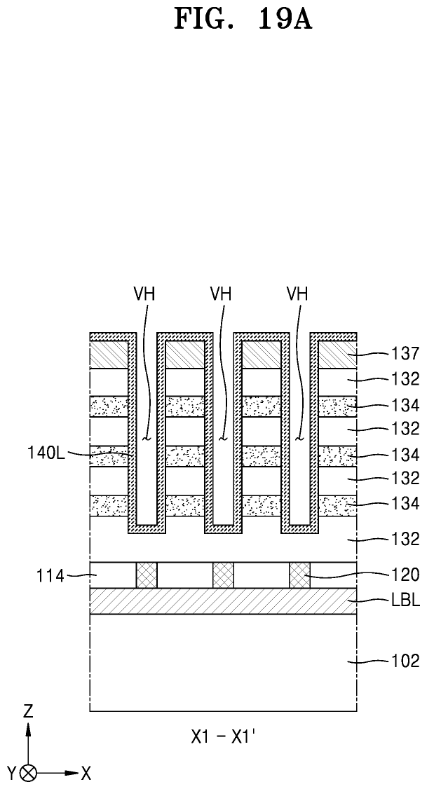

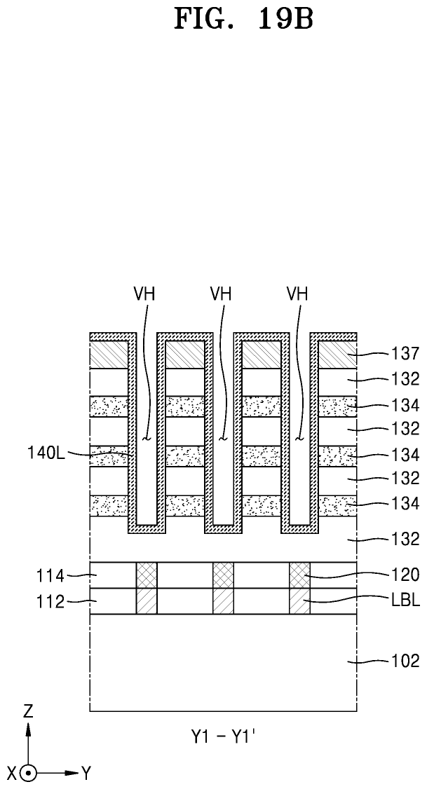

Referring to FIGS. 19A and 19B, a variable resistive layer 140L may conformally cover exposed inner surfaces of the plurality of vertical holes VH and a top surface of the top sacrificial insulating film 137. The variable resistive layer 140L may include an OTS material.

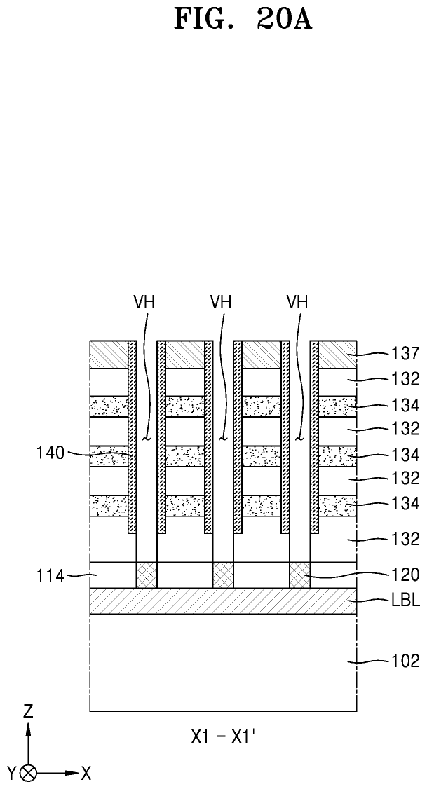

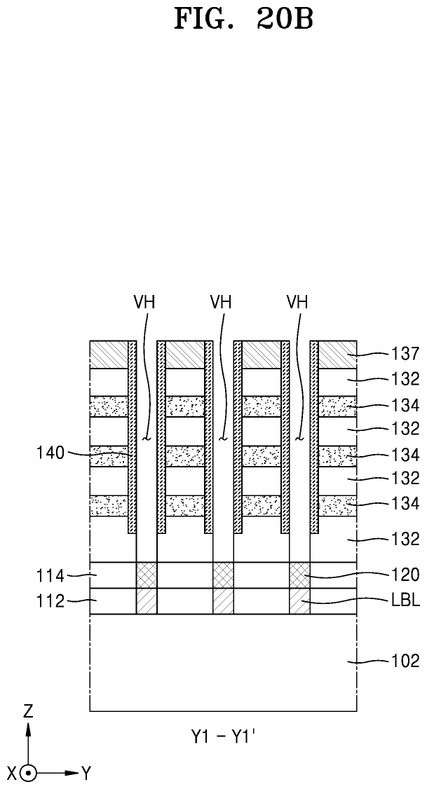

Referring to FIGS. 20A and 20B, the variable resistive layer 140L may be etched back by using an anisotropic etching process from the resultant structure of FIGS. 19A and 19B, and thus, the lowest one of the isolation insulating films 132 may be exposed in the bottom surface of each of the plurality of vertical holes VH. The exposed lowest one of the isolation insulating films 132 may be anisotropically etched to expose the plurality of resistive layers 120 through the plurality of vertical holes VH. As a result, a plurality of cell variable resistive layers 140 respectively covering inner sidewalls of the plurality of vertical holes VH may be obtained from the variable resistive layer 140L, and the top surface of the top sacrificial insulating film 137 may be exposed between two adjacent ones of the plurality of cell variable resistive layers 140.

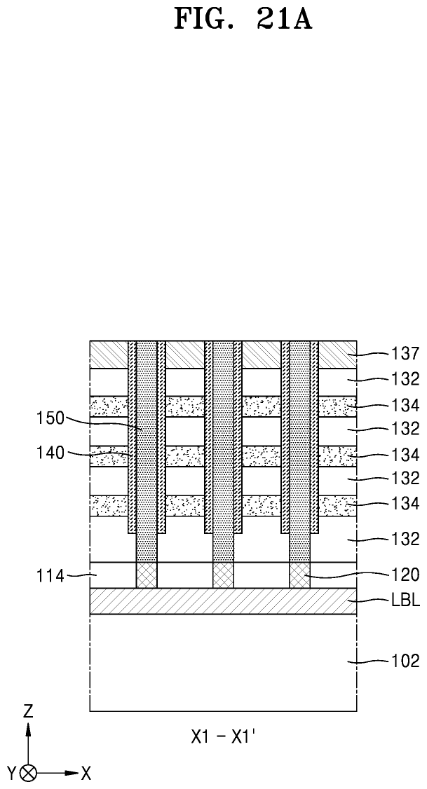

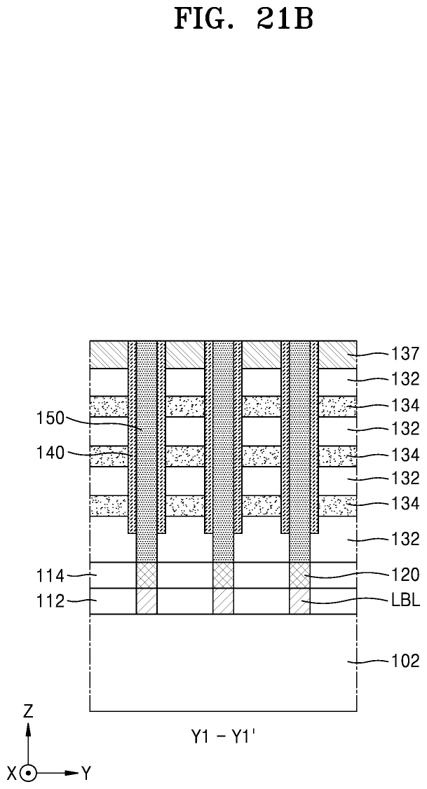

Referring to FIGS. 21A and 21B, in the resultant structure of FIGS. 20A and 20B, a plurality of conductive pillars 150 may fill the plurality of vertical holes VH.

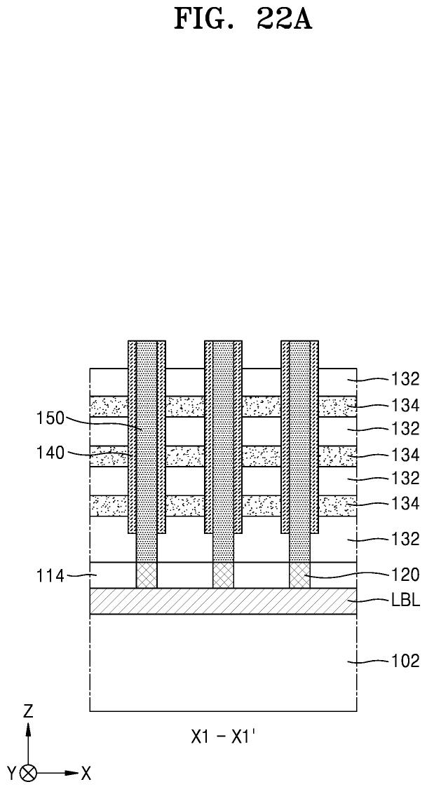

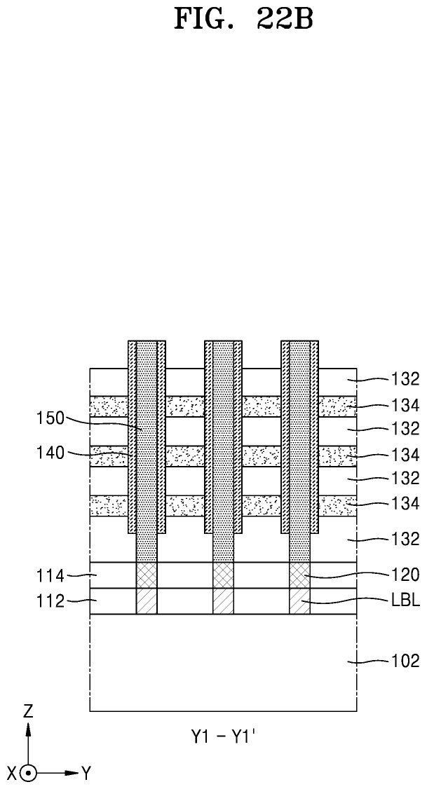

Referring to FIGS. 22A and 22B, the top sacrificial insulating film 137 may be removed from the resultant structure of FIGS. 21A and 21B, and thus, an upper sidewall of each of the plurality of cell variable resistive layers 140 and a top surface of an uppermost one of the plurality of isolation insulating films 132 may be exposed.

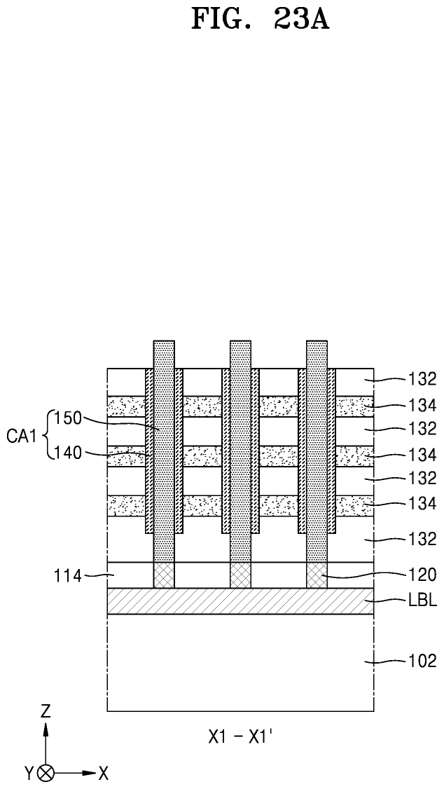

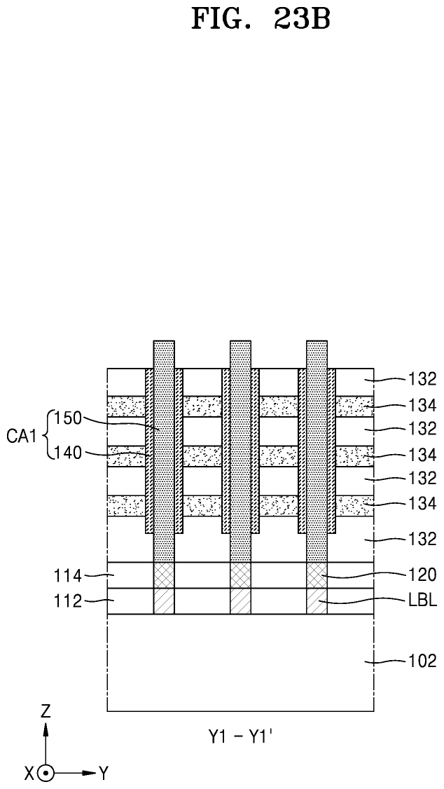

Referring to FIGS. 23A and 23B, in the resultant structure of FIGS. 22A and 22B, exposed portions of the plurality of cell variable resistive layers 140 may be removed to expose respective upper sidewalls of the plurality of conductive pillars 150.

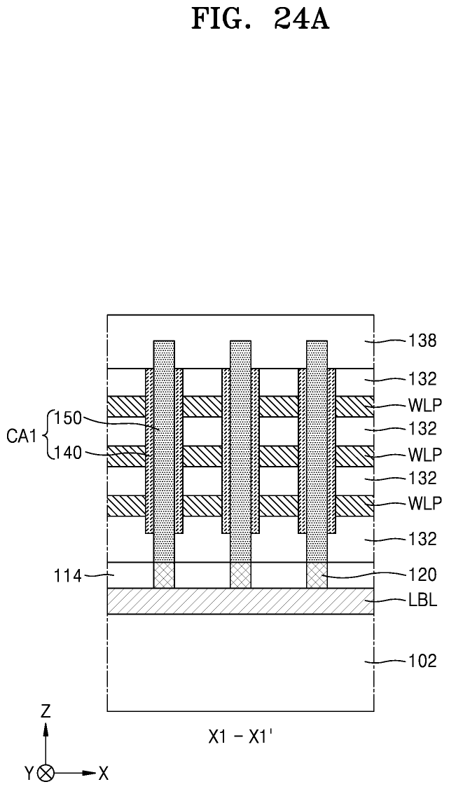

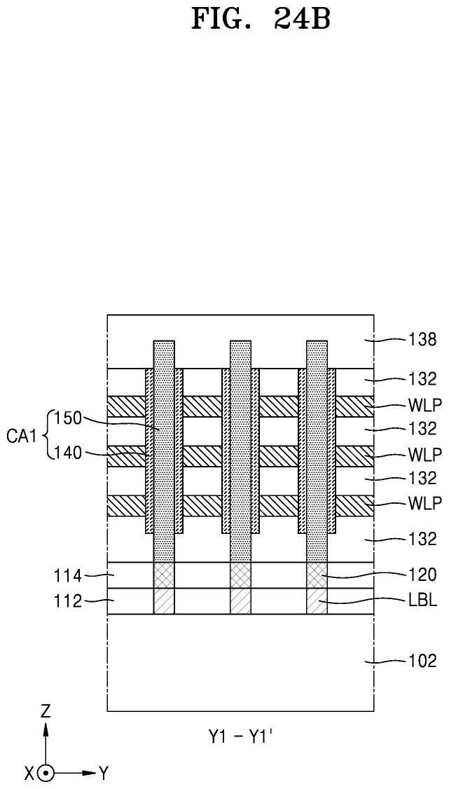

Referring to FIGS. 24A and 24B, in the resultant structure of FIGS. 23A and 23B, an upper insulating film 138 may cover respective upper portions of the plurality of conductive pillars 150 and the top surface of the uppermost one of the isolation insulating films 132.

Afterwards, a process of replacing the plurality of sacrificial insulating films 134 by a plurality of word line plates WLP may be performed. To this end, a partial region of each of the stack structure of the plurality of isolation insulating films 132 and the plurality of sacrificial insulating films 134 and the upper insulating film 138 may be etched from other regions, which are not shown on the substrate 102 in FIGS. 24A and 24B, to form a plurality of cut regions exposing a portion of each of the plurality of isolation insulating films 132 and the plurality of sacrificial insulating films 134. Thereafter, the plurality of sacrificial insulating films 134 may be removed through the plurality of cut regions to prepare a plurality of word line spaces, and the plurality of word line spaces may be filled by a plurality of word line plates WLP.

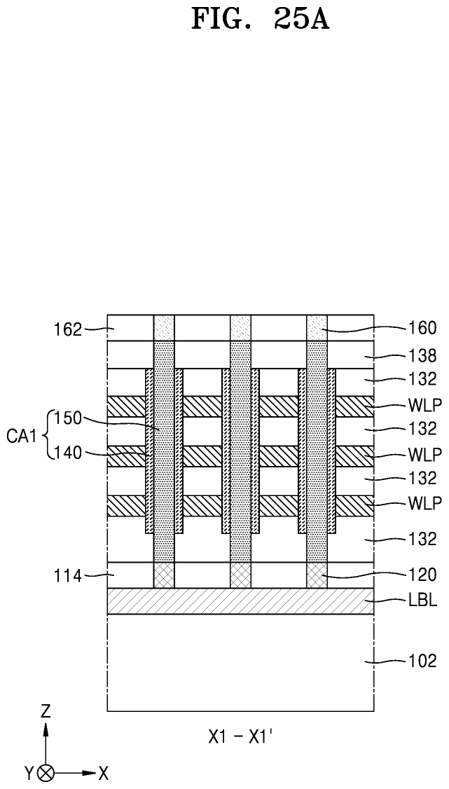

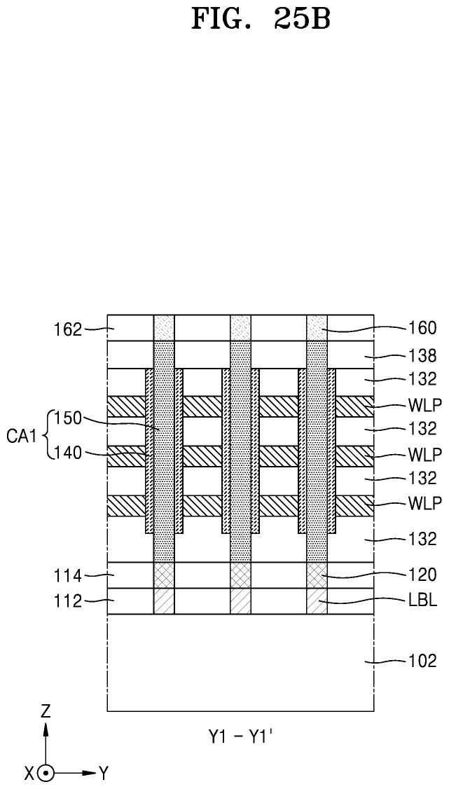

Referring to FIGS. 25A and 25B, in the resultant structure of FIGS. 24A and 24B, an upper portion of the upper insulating film 138 may be removed to expose a top surface of each of the plurality of conductive pillars 150, and thus, a thickness of the upper insulating film 138 may be reduced. Afterwards, a plurality of selectors 160 and a second insulating plate 162 may be formed on the plurality of conductive pillars 150. The plurality of selectors 160 may be connected to the plurality of conductive pillars 150, and the second insulating plate 162 may fill a space between two adjacent ones of the plurality of selectors 160.

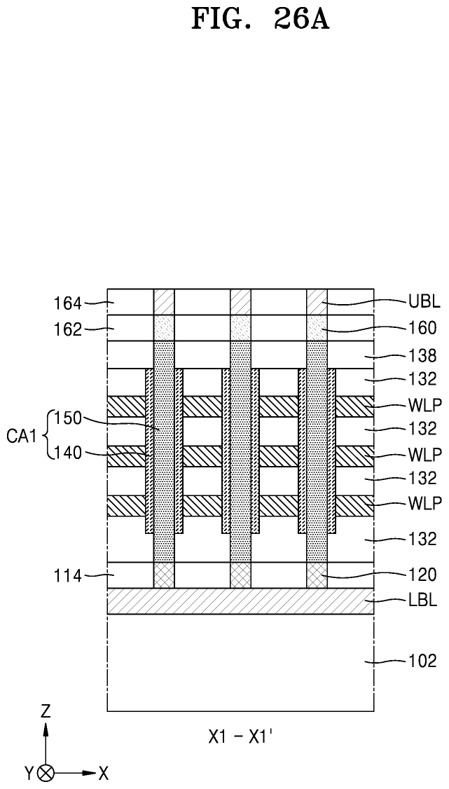

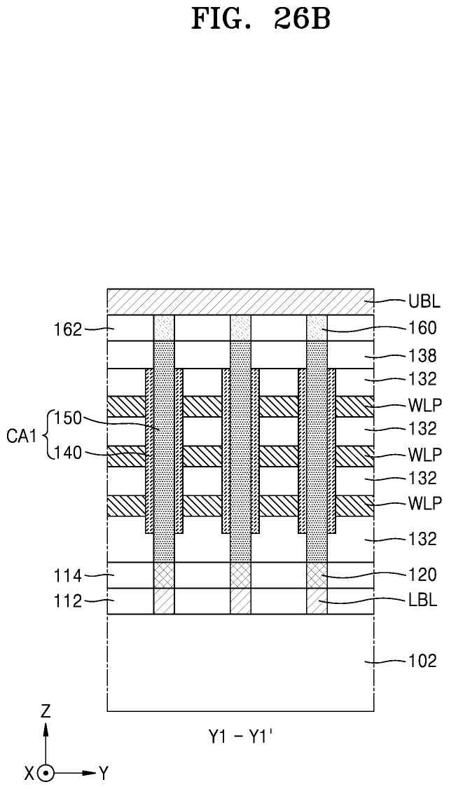

Referring to FIGS. 26A and 26B, a plurality of second bit lines UBL may be respectively connected to the plurality of selectors 160, and a second insulating pattern 164 may fill a space between two adjacent ones of the plurality of second bit lines UBL. As a result, the vertical memory device 100 shown in FIGS. 1 and 2A to 2C may be manufactured.

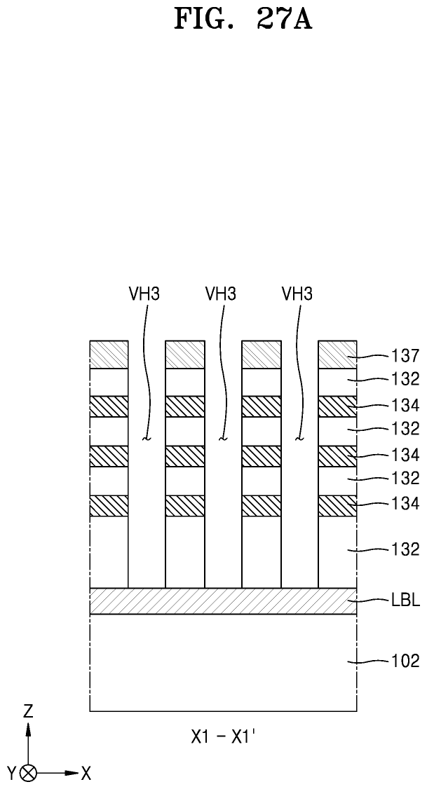

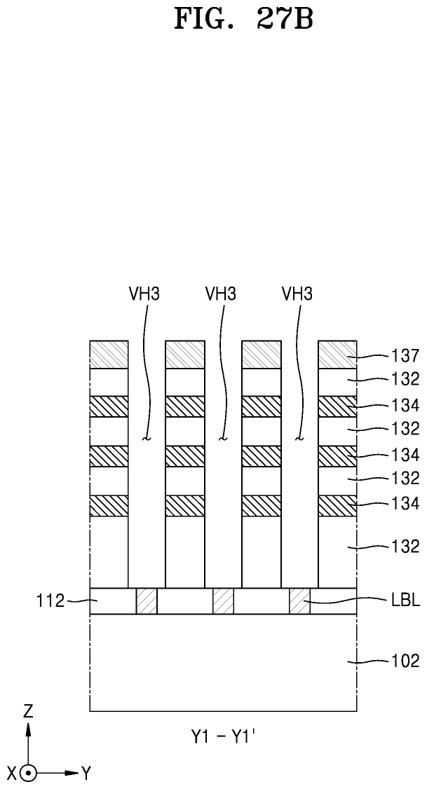

FIGS. 27A to 29B are cross-sectional views illustrating a method of manufacturing a vertical memory device, according to embodiments of the present disclosure. FIGS. 27A, 28A, and 29A are cross-sectional views of a portion corresponding to a cross-section taken along line X1-X1′ of FIG. 1, according to a process sequence. FIGS. 27B, 28B, and 29B are cross-sectional views of a portion corresponding to a cross-section taken along line Y1-Y1′ of FIG. 1. An example of a method of manufacturing the vertical memory device 300 shown in FIGS. 6A and 6B is described with reference to FIGS. 27A to 29B. In FIGS. 27A to 29B, the same reference numerals may be used to denote the same elements as in FIGS. 1 to 26B, and to the extent that an element has not been described herein, it may be assumed that the element is at least similar to a corresponding element that has been described elsewhere within the present disclosure.

Referring to FIGS. 27A and 27B, the processes described with reference to FIGS. 16A to 17B may be performed. However, processes of forming the plurality of resistive layers 120 and the first insulating plate 114 described with reference to FIGS. 16A and 16B may be omitted.

Afterwards, in a like manner to that described with reference to FIGS. 18A and 18B, respective partial regions of the top sacrificial insulating film 137, the plurality of isolation insulating films 132, and the plurality of sacrificial insulating films 134 may be etched, and thus, a plurality of vertical holes VH3 exposing the plurality of first bit lines LBL may be formed.

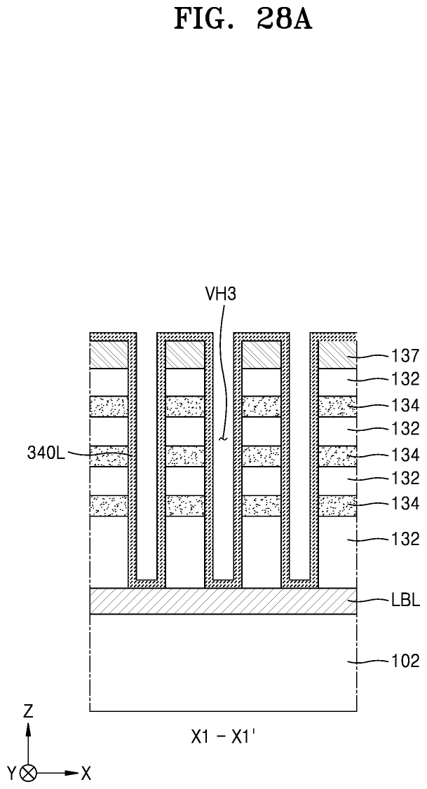

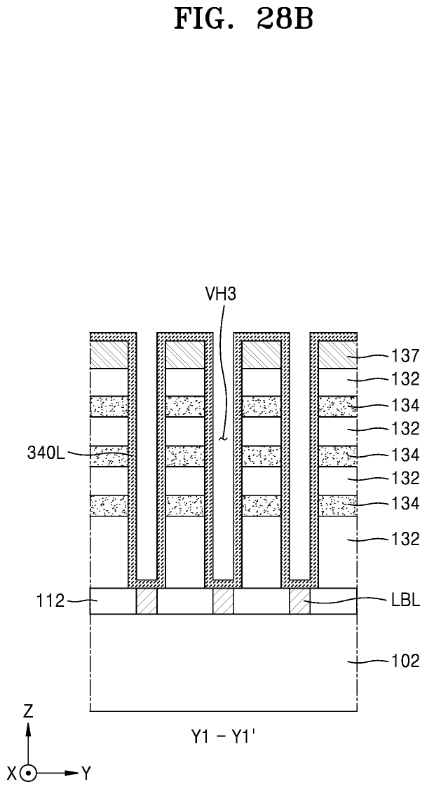

Referring to FIGS. 28A and 28B, a variable resistive layer 340L may conformally cover exposed inner surfaces of the plurality of vertical holes VH3 and a top surface of the top sacrificial insulating film 137. The variable resistive layer 340L may include an OTS material.

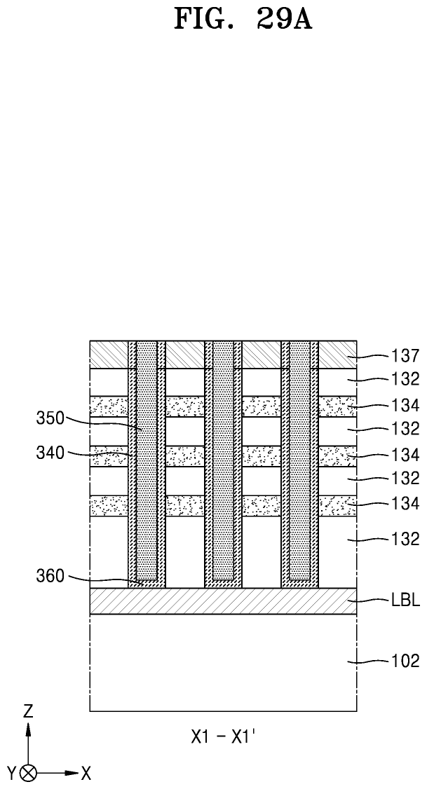

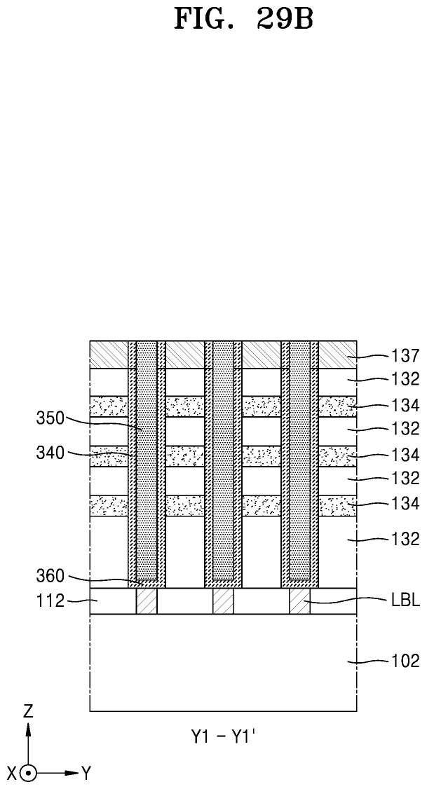

Referring to FIGS. 29A and 29B, in the resultant structure of FIGS. 28A and 28B, a conductive layer may have a sufficient thickness so as to fill the plurality of vertical holes VH3 remaining on the variable resistive layer 340L. Thereafter, the variable resistive layer 340L and the conductive layer may be planarized to expose a top surface of the top sacrificial insulating film 137. Thus, a plurality of cell variable resistive layers 340 and a plurality of conductive pillars 350 may be formed. The plurality of cell variable resistive layers 340 may include portions of the variable resistive layer 340L, which remain inside the plurality of vertical holes VH3, and the plurality of conductive pillars 350 may include portions of the conductive layer, which remain inside the plurality of vertical holes VH3.

Afterwards, the processes described with reference to FIGS. 21A to 24B may be performed, and a plurality of resistive layers 320 and a second insulating plate 162 may be formed. The plurality of resistive layers 320 may be connected to the plurality of conductive pillars 350 on the plurality of conductive pillars 350, and the second insulating plate 162 may fill a space between two adjacent ones of the plurality of resistive layers 320. A plurality of second bit lines UBL and a second insulating pattern 164 filling a space between two adjacent ones of the plurality of second bit lines UBL may be formed in a like manner to that described with reference to FIGS. 26A and 26B. As a result, the vertical memory device 300 shown in FIGS. 6A and 6B may be manufactured.

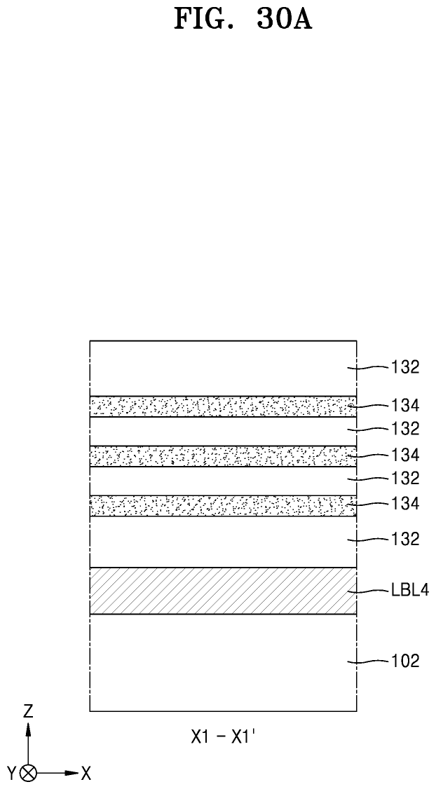

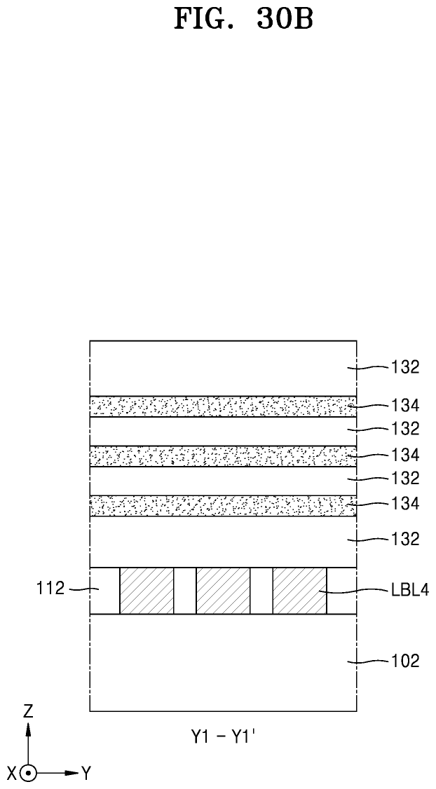

FIGS. 30A to 34B are cross-sectional views illustrating a method of manufacturing a vertical memory device, according to embodiments of the present disclosure. FIGS. 30A, 31A, 32A, 33A, and 34A are cross-sectional views of a portion corresponding to a cross-section taken along line X1-X1′ of FIG. 1, according to a process sequence. FIGS. 30B, 31B, 32B, 33B, and 34B are cross-sectional views of a portion corresponding to a cross-section taken along line Y1-Y1′ of FIG. 1. An example of a method of manufacturing the vertical memory device 500 shown in FIGS. 9A and 9B is described with reference to FIGS. 30A to 34B. In FIGS. 30A to 34B, the same reference numerals may be used to denote the same elements as in FIGS. 1 to 29B, and to the extent that an element has not been described herein, it may be assumed that the element is at least similar to a corresponding element that has been described elsewhere within the present disclosure.

Referring to FIGS. 30A and 30B, a plurality of first bit lines LBL4 and a plurality of first insulating patterns 112 may be formed on a substrate 102. The plurality of first insulating patterns 112 may fill respective spaces between the plurality of first bit lines LBL4. Thereafter, in a like manner to that described with reference to FIGS. 17A and 17B, a plurality of isolation insulating films 132 and a plurality of sacrificial insulating films 134 may be alternately one-by-one stacked on the plurality of first bit lines LBL4 and the plurality of first insulating patterns 112. A lowermost one of the isolation insulating films 132, which is closest to the substrate 102, and an uppermost one of the isolation insulating films 132, which is farthest from the substrate 102, may have greater thicknesses than other isolation insulating films 132 in a vertical direction (e.g., Z direction).

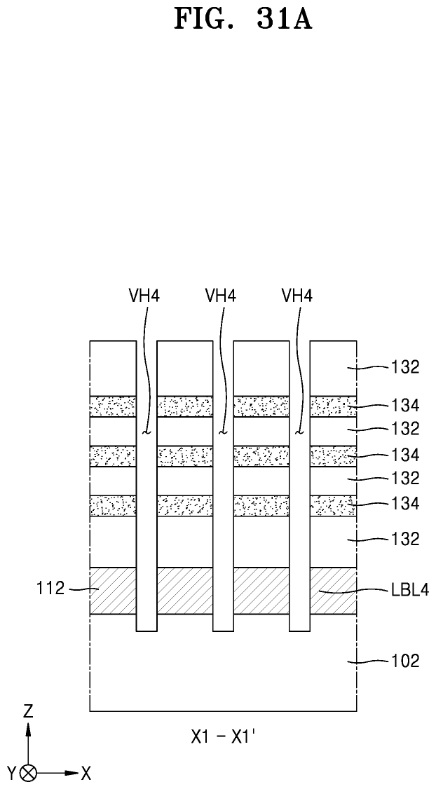

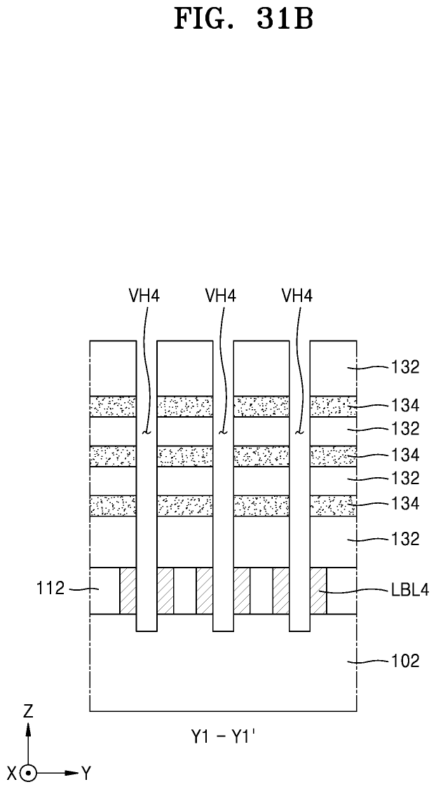

Referring to FIGS. 31A and 31B, respective partial regions of the plurality of isolation insulating films 132, the plurality of sacrificial insulating films 134, and the plurality of first bit lines LBL4 may be etched to form a plurality of vertical holes VH4. The plurality of vertical holes VH4 may completely pass through the plurality of first bit lines LBL4 in the vertical direction (e.g., Z direction), and the substrate 102 may be exposed at bottom surfaces of the plurality of vertical holes VH4.

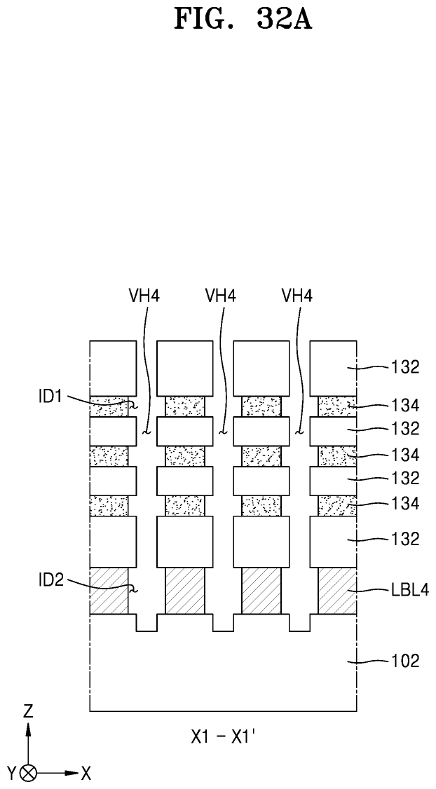

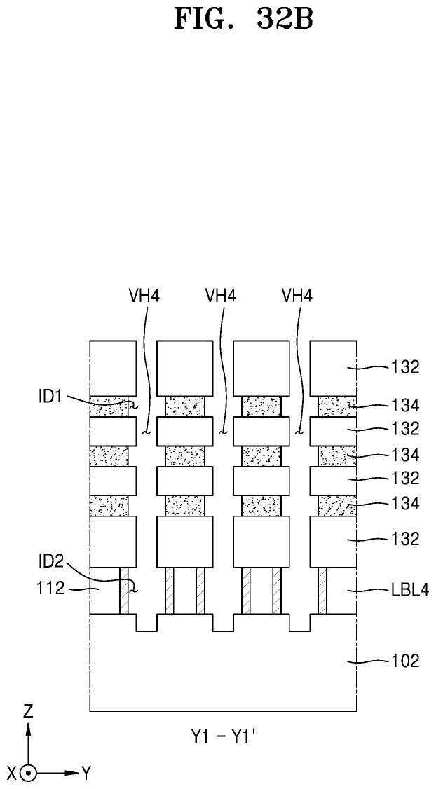

Referring to FIGS. 32A and 32B, in the resultant structure of FIGS. 31A and 32B, partial regions may be removed from respective sidewalls of the plurality of sacrificial insulating films 134 and the plurality of first bit lines LBL4, which are exposed through the plurality of vertical holes VH4. Thus, a plurality of indent spaces (e.g., ID1 and ID2), which are connected to the plurality of vertical holes VH4, may be formed. The plurality of indent spaces (e.g., ID1 and ID2) may include an indent space ID1 defined by the sacrificial insulating film 134 and an indent space ID2 defined by the first bit line LBL4.

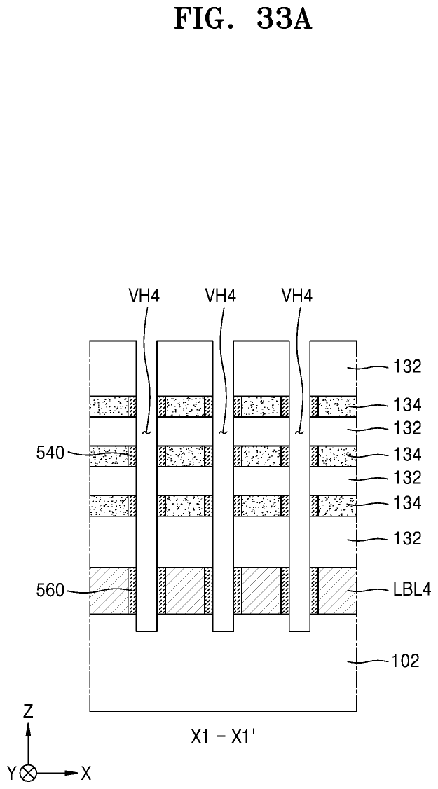

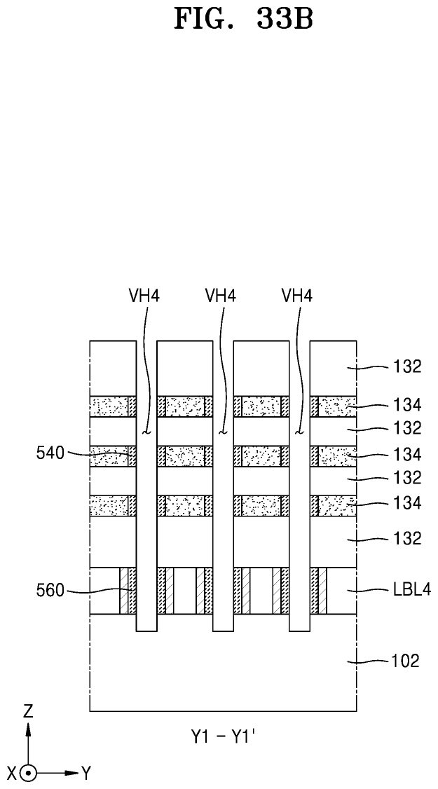

Referring to FIGS. 33A and 33B, in the resultant structure of FIGS. 33A and 33B, an OTS material may fill the plurality of indent spaces (e.g., ID1 and ID2) and cover respective inner surfaces of a plurality of vertical holes VH4. Thereafter, the OTS material film may be etched back, and thus, only portions of the OTS material film, which fill the plurality of indent spaces (e.g., ID1 and ID2), may be left. Portions of the OTS material film, which fill the plurality of indent spaces ID1, may constitute a plurality of cell variable resistive layers 540, and portions of the OTS material film, which fill the plurality of indent spaces ID2, may constitute a plurality of selectors 560.

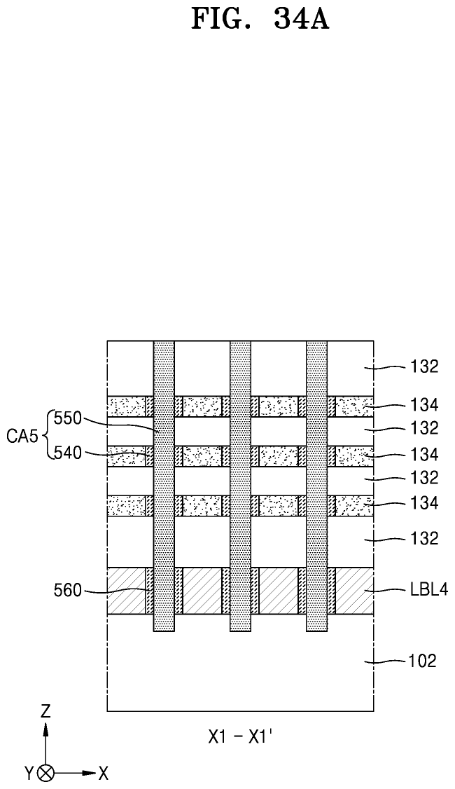

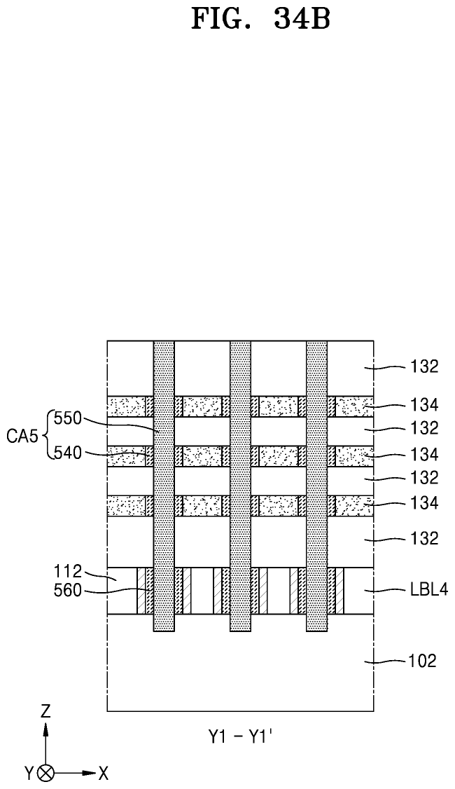

Referring to FIGS. 34A and 34B, in the resultant structure of FIGS. 33A and 33B, a conductive layer may have a sufficient thickness so as to fill the plurality of vertical holes VH4. Thereafter, the conductive layer may be planarized to expose a top surface of the uppermost one of the isolation insulating films 132 to form a plurality of conductive pillars 550. The plurality of conductive pillars 550 may include portions of the conductive layer, which remain inside the plurality of vertical holes VH4.

Afterwards, the processes described with reference to FIGS. 21A to 24B may be performed, and a plurality of resistive layers 320 and a second insulating plate 162 may be formed. The plurality of resistive layers 320 may be connected to the plurality of conductive pillars 550 on the plurality of conductive pillars 550, and the second insulating plate 162 may fill a space between two adjacent ones of the plurality of resistive layers 320. A plurality of second bit lines UBL and a second insulating pattern 164 filling a space between two adjacent ones of the plurality of second bit lines UBL may be formed in a like manner to that described with reference to FIGS. 26A and 26B. As a result, the vertical memory device 500 shown in FIGS. 9A and 9B may be manufactured.

Although the methods of manufacturing the vertical memory device 100 shown in FIGS. 1 and 2A to 2C, the vertical memory device 300 shown in FIGS. 6A and 6B, and the vertical memory device 500 shown in FIGS. 9A and 9B have been described with reference to FIGS. 16 to 34B, it will be understood that the vertical memory devices 100A, 100B, 200, 400, 400A, 600, and 700 shown in FIGS. 3 to 5B, 7A to 8B, 10, and 11 and vertical memory devices having variously changed structures may be manufactured by applying various modifications and changes to the processes described with reference to FIGS. 16 to 34B within the scope of the inventive concept.

Terms such as “first” and “second” may be used herein merely to describe a variety of constituent elements, but the constituent elements are not necessarily limited by the terms. Such terms are used for the purpose of distinguishing one constituent element from another constituent element. Thus, without departing from the right scope of the present inventive concept, a first constituent element may be referred to as a second constituent element, and vice versa.

Terms that describe spatial relationships, such as “below,” “lower,” “above,” “upper” and the like, may be used herein for ease of description to describe one element or feature's relationship to another element(s) or feature(s) as illustrated in the figures. It will be understood that such terms are intended to encompass different orientations of the device in use or operation in addition to the orientation(s) depicted in the figures. For example, if the device in the figures is turned over, elements described as “below” or “beneath” other elements or features would then be oriented “above” the other elements or features.

While the inventive concept has been particularly shown and described with reference to embodiments thereof, it will be understood that various changes in form and details may be made therein without departing from the spirit and scope of the present disclosure.

What is claimed is:

1. A vertical memory device, comprising:
a memory cell structure extending primarily in a vertical direction;
a resistive layer electrically connected to a first end of the memory cell structure;
a selector electrically connected to a second end of the memory cell structure, the selector comprising a variable resistive material of which an electrical resistive value is reversibly changed in response to an electrical signal;
a first bit line spaced apart from the memory cell structure in the vertical direction with the resistive layer disposed therebetween, the first bit line being electrically connected to the resistive layer;
a second bit line spaced apart from the memory cell structure in the vertical direction with the selector disposed therebetween, the second bit line being electrically connected to the selector; and
a plurality of word line plates spaced apart from each other in the vertical direction and overlapping each other in the vertical direction, each of the plurality of word line plates at least partially surrounding a portion of a sidewall of the memory cell structure.

2. The vertical memory device of claim 1, wherein the selector comprises an ovonic threshold switching (OTS) material layer.

3. The vertical memory device of claim 1, wherein the memory cell structure comprises:
a conductive pillar comprising a first end portion in contact with the resistive layer and a second end portion in contact with the selector, the conductive pillar extending primarily in the vertical direction; and
a cell variable resistive layer disposed between the conductive pillar and the plurality of word line plates, the cell variable resistive layer being in contact with each of the conductive pillar and the plurality of word line plates,
wherein each of the selector and the cell variable resistive layer comprises an OTS material layer.

4. The vertical memory device of claim 3, wherein the selector and the cell variable resistive layer are spaced apart from each other in the vertical direction.

5. The vertical memory device of claim 3, wherein the selector and the cell variable resistive layer are physically and integrally connected to each other.

6. The vertical memory device of claim 1, wherein the selector passes through at least a portion of the second bit line in the vertical direction.

7. The vertical memory device of claim 1, wherein the memory cell structure comprises:
a conductive pillar comprising a first end portion in contact with the resistive layer and a second end portion in contact with the selector, the conductive pillar extending primarily in the vertical direction; and
a plurality of cell variable resistive layers disposed between the conductive pillar and the plurality of word line plates,
wherein the plurality of cell variable resistive layers are spaced apart from each other in the vertical direction and overlap each other in the vertical direction,
wherein each of the plurality of cell variable resistive layers is in contact with a selected one of the plurality of word line plates and the conductive pillar, and
wherein each of the selector and the cell variable resistive layer comprises an OTS material layer.

8. The vertical memory device of claim 1, wherein the first bit line and the second bit line extend primarily in directions intersecting each other.

9. The vertical memory device of claim 1, further comprising a substrate configured to support the memory cell structure,
wherein the first bit line and the resistive layer are disposed between the substrate and the memory cell structure in the vertical direction, and
wherein the second bit line and the selector are spaced apart from the substrate in the vertical direction with the memory cell structure disposed therebetween.

10. The vertical memory device of claim 1, further comprising a substrate configured to support the memory cell structure,
wherein the selector is disposed between the substrate and the memory cell structure in the vertical direction, and
wherein the resistive layer is spaced apart from the substrate in the vertical direction with the memory cell structure disposed therebetween.

11. A vertical memory device, comprising:
a plurality of memory cell structures repeatedly arranged in a first lateral direction and a second lateral direction that intersect with each other, each of the plurality of memory cell structures extending primarily in a vertical direction;
a plurality of resistive layers, each of the plurality of resistive layers being electrically connected to a first end of a corresponding one of the plurality of memory cell structures in the vertical direction;
a plurality of selectors, each of the plurality of selectors being electrically connected to another one of a corresponding one of the plurality of memory cell structures in the vertical direction and comprising a variable resistive material of which an electrical resistive value is reversibly changed in response to an electrical signal;
a plurality of first bit lines spaced apart from the plurality of memory cell structures in the vertical direction with the plurality of resistive layers disposed therebetween, each of the plurality of first bit lines being electrically connected to a series of resistive layers arranged in a line in the first lateral direction, from among the plurality of resistive layers;
a plurality of second bit lines spaced apart from the plurality of memory cell structures in the vertical direction with the plurality of selectors disposed therebetween, each second bit line being electrically connected to a series of selectors arranged in a line in the second lateral direction, from among the plurality of selectors; and
a plurality of word line plates spaced apart from each other in the vertical direction and overlapping each other in the vertical direction, each of the plurality of word line plates at least partially surrounding a portion of a sidewall of each of the plurality of memory cell structures.

12. The vertical memory device of claim 11, wherein each of the plurality of memory cell structures comprises:
a conductive pillar comprising a first end portion and a second end portion, the first end portion being in contact with a selected one of the plurality of resistive layers, the second end portion being in contact with a selected one of the plurality of selectors, and the conductive pillar extending primarily in the vertical direction; and
a cell variable resistive layer disposed between the conductive pillar and the plurality of word line plates, the cell variable resistive layer being in contact with each of the conductive pillar and the plurality of word line plates,
wherein each of the cell variable resistive layer and the plurality of selectors in each of the plurality of memory cell structures comprises an ovonic threshold switching (OTS) material layer.

13. The vertical memory device of claim 11, wherein, a selected memory cell structure from among the plurality of memory cell structures comprises:
a first conductive pillar comprising a first end portion and a second end portion, the first end portion being in contact with a first selective layer that is selected from the plurality of resistive layers, the second end portion being in contact with a first selector selected from the plurality of selectors; and
a first cell variable resistive layer disposed between the first conductive pillar and the plurality of word line plates, the first cell variable resistive layer being in contact with a sidewall of the first conductive pillar,
wherein the first selector and the first cell variable resistive layer are spaced apart from each other in the vertical direction.

14. The vertical memory device of claim 11, wherein a selected one of the plurality of memory cell structures comprises:
a first conductive pillar comprising a first end portion and a second end portion, the first end portion being in contact with a first resistive layer selected from the plurality of resistive layers, the second end portion being in contact with a first selector selected from the plurality of selectors; and
a first cell variable resistive layer disposed between the first conductive pillar and the plurality of word line plates, the first cell variable resistive layer being in contact with a sidewall of the first conductive pillar,
wherein the first selector and the first cell variable resistive layer are physically and integrally connected to each other.

15. The vertical memory device of claim 11, wherein a selected one of the plurality of memory cell structures comprises:
a first conductive pillar comprising a first end portion and a second end portion, the first end portion being in contact with a first resistive layer selected from the plurality of resistive layers, the second end portion being in contact with a first selector selected from the plurality of selectors; and
at least one first cell variable resistive layer disposed between the first conductive pillar and at least one word line plate selected from the plurality of word line plates,
wherein each of the first conductive pillar and the first selector passes through at least a portion of a selected one of the plurality of second bit lines in the vertical direction.

16. The vertical memory device of claim 11, wherein a selected one of the plurality of memory cell structures comprises:
a first conductive pillar comprising a first end portion and a second end portion, the first end portion being in contact with a first resistive layer selected from the plurality of resistive layers, the second end portion being in contact with a first selector selected from the plurality of selectors; and
a plurality of cell variable resistive layers, each of the plurality of cell variable resistive layers being disposed between the first conductive pillar and a selected one of the plurality of word line plates and being in contact with a sidewall of the first conductive pillar,
wherein the plurality of cell variable resistive layers are spaced apart from each other in the vertical direction and overlap each other in the vertical direction,
wherein the first conductive pillar and the first selector pass through a selected one of the plurality of second bit lines in the vertical direction, and
wherein each of the first selector and the plurality of cell variable resistive layers comprises an ovonic threshold switching (OTS) material layer.

17. The vertical memory device of claim 11, further comprising:
a substrate configured to support the plurality of memory cell structures; and
a peripheral circuit structure spaced apart from the plurality of memory cell structures in the vertical direction with the substrate disposed therebetween.

18. The vertical memory device of claim 11, wherein each of the plurality of word line plates comprises a flat plate having a plurality of through holes through which the plurality of memory cell structures respectively pass in the vertical direction.

19. The vertical memory device of claim 11, wherein the plurality of word line plates comprise a first local word line plate and a second local word line plate, the first local word line plate and the second local word line plate being spaced apart from each other in a lateral direction at the same vertical level,
wherein the first local word line plate and the second local word line plate each have a comb shape comprising a plurality of protrusion electrode portions constituting interdigitated electrodes,
wherein each of the plurality of memory cell structures extends primarily in the vertical direction between the protrusion electrode portion of the first local word line plate and the protrusion electrode portion of the second local word line plate, and
wherein each of the plurality of memory cell structures comprises a conductive pillar and a cell variable resistive layer, the conductive pillar being spaced apart from each of the first local word line plate and the second local word line plate, the cell variable resistive layer at least partially surrounding the conductive pillar and being in contact with each of the first local word line plate and the second local word line plate.

20. A vertical memory device, comprising:
a plurality of memory cell structures repeatedly arranged in a first lateral direction and a second lateral direction that intersect with each other, each of the plurality of memory cell structures extending primarily in a vertical direction, and comprising a conductive pillar and at least one cell variable resistive layer at least partially surrounding the conductive pillar, the at least one cell variable resistive layer comprising a first ovonic threshold switching (OTS) material layer;
a plurality of resistive layers, each of the plurality of resistive layers being electrically connected to a first end of a corresponding one of the plurality of memory cell structures;
a plurality of selectors, each of the plurality of selectors being electrically connected to a second end of a corresponding one of the plurality of memory cell structures and comprising a second OTS material layer;
a plurality of first bit lines, each of the plurality of first bit lines being electrically connected to a series of resistive layers arranged in a line in the first lateral direction, from among the plurality of resistive layers;
a plurality of second bit lines, each of the plurality of second bit lines being electrically connected to a series of selectors arranged in a line in the second lateral direction, from among the plurality of selectors; and
a plurality of word line plates being spaced apart from each other in the vertical direction and overlapping each other in the vertical direction, each of the plurality of word line plates at least partially surrounding a portion of a sidewall of each of the plurality of memory cell structures.
